(19) United States
(12) Patent Application Publication
(10) Pub. No.: US 2024/0282595 A1
(43) Pub. Date: Aug. 22, 2024

(54) MODULAR SUBSTRATE ASSEMBLY AND SYSTEM INCORPORATING SAME

(71) Applicant: Ichor Systems, Inc., Fremont, CA (US)

(72) Inventor: Stephen CARSON, Woodstock, NY (US)

(21) Appl. No.: 18/437,373

(22) Filed: Feb. 9, 2024

Related U.S. Application Data
(60) Provisional application No. 63/446,089, filed on Feb. 16, 2023.

(51) Int. Cl. H01L 21/67; F16L 41/03

(52) U.S. Cl. CPC H01L 21/67017; F16L 41/03

(57) ABSTRACT

Apparatuses for controlling fluid flow are important components for delivering process fluids for semiconductor fabrication. These apparatuses for controlling fluid flow frequently rely on substrate blocks to conduct fluid between components in the apparatuses for controlling fluid flow. Modular substrate assemblies which allow flexible configuration of the flow paths within the apparatuses for controlling flow. These modular substrate assemblies may incorporate a plurality of substrate blocks, each of the substrate blocks connected via one or more connectors. A channel may extend through the connectors to form a portion of a flow path within the substrate assembly.

### CROSS-REFERENCE TO RELATED APPLICATIONS

This application claims the benefit of U.S. Provisional Application 63/446,089, filed Feb. 16, 2023, which is incorporated herein by reference in its entirety.

### BACKGROUND OF THE INVENTION

Flow control has been one of the key technologies in semiconductor chip fabrication. Apparatuses for controlling fluid flow are important for delivering known flow rates of process fluids for semiconductor fabrication and other industrial processes. Such devices are used to measure and accurately control the flow of fluids for a variety of applications. This control relies on substrate assemblies which enable flexible configuration of components to create apparatuses for controlling fluid flow and fluid delivery modules comprising one or more apparatuses for controlling fluid flow.

As the technology of chip fabrication has improved, so has the demand on the apparatuses for controlling flow. Semiconductor fabrication processes increasingly require increased performance, including more accurate measurements, lower equipment costs, improved transient response times, and more consistency in timing in the delivery of gases. In order to improve cost of equipment and modularity of components, improved substrate assemblies are desired.

### SUMMARY OF THE INVENTION

The present technology is directed to a substrate assembly for use in a mass flow controller or other gas or liquid delivery device. One or more of these gas or liquid delivery devices may be used in a wide range of processes such as semiconductor chip fabrication, solar panel fabrication, etc.

In one implementation, the invention is a system for processing articles. The system has a fluid supply configured to supply a process fluid, a process chamber configured to process articles, and a fluid delivery module. The fluid delivery module has an inlet fluidly coupled to the fluid supply, an outlet fluidly coupled to the process chamber, a flow passage extending from the inlet to the outlet, and a substrate panel. The fluid delivery module further has a first component for controlling flow, a substrate assembly, and a seal. The first component for controlling flow has a first port having a seal cavity, a second port having a seal cavity, and a first flow path extending from the first port to the second port, the first flow path forming a first portion of the flow passage. The substrate assembly includes a first substrate block and a second substrate block. The first substrate block has a first port, a first male connector, and a first female connector, the first port having a seal cavity. The second substrate block has a first port, a first male connector, and a first female connector, the first port having a seal cavity. A second flow path extends from the first port of the first substrate block to the first port of the second substrate block, the second flow path forming a second portion of the flow passage. The seal is positioned within the seal cavity of the first port of the first component and the seal cavity of the insert of the first port of the first substrate block. The first port of the first component is coupled to the first port of the first substrate block of the substrate assembly so that the first flow path is fluidly coupled to the second flow path.

In another implementation, the invention is a system for processing articles. The system has a fluid supply configured to supply a process fluid, a process chamber configured to process articles, and a fluid delivery module. The fluid delivery module has an inlet fluidly coupled to the fluid supply, an outlet fluidly coupled to the process chamber, a flow passage extending from the inlet to the outlet, and a substrate panel. The fluid delivery module further has a first component for controlling flow and a substrate assembly. The first component for controlling flow has a first port, a second port, and a first flow path extending from the first port to the second port, the first flow path forming a first portion of the flow passage. The substrate assembly includes a first substrate block and a second substrate block. The first substrate block has a first port, a first male connector, and a first female connector. The second substrate block has a first port, a first male connector, and a first female connector. The first male connector of the first substrate block is coupled to the first female connector of the second substrate block and the first female connector of the first substrate block is coupled to the first male connector of the second substrate block. A second flow path extends from the first port of the first substrate block to the first port of the second substrate block, the second flow path forming a second portion of the flow passage. The first port of the first component is coupled to the first port of the first substrate block of the substrate assembly so that the first flow path is fluidly coupled to the second flow path.

In yet another implementation, the invention is a substrate assembly, the substrate assembly having a first substrate block and a second substrate block. The first substrate block has a first port, a first male connector, a first female connector, a first passage, and a first channel. The first passage extends from the first port to the first channel and the first channel extends from the first passage to the first male connector. The second substrate block has a first male connector, a first female connector, a second male connector, a second female connector, and a first channel extends from the first female connector to the second male connector. A first flow path extends from the first port to the second male connector via the first passage of the first substrate block, the first channel of the substrate block, and the first channel of the second substrate block.

In another implementation, the invention is a substrate assembly, the substrate assembly having first and second end substrate blocks and a plurality of connector substrate blocks. Each of the first end substrate block has a first port and a first connector. Each of the plurality of connector substrate blocks has a first connector and a second connector. The first end substrate block is joined to a first one of the plurality of connector substrate blocks. The first connector of the first end substrate block engages the first connector of the first one of the plurality of connector substrate blocks. The second end substrate block is joined to a second one of the plurality of connector substrate blocks. The first connector of the second end substrate block engages the second connector of the second one of the plurality of connector substrate blocks. A first flow path extends from the first port of the first end substrate block through the first connector of the first end substrate block to the first one of the plurality of connector substrate blocks.

In yet another implementation, the invention is a system for processing articles. The system has a fluid supply configured to supply a process fluid, a process chamber configured to process articles, and a fluid delivery module. The fluid delivery module has an inlet fluidly coupled to the fluid supply, an outlet fluidly coupled to the process chamber, a flow passage extending from the inlet to the outlet, and a substrate panel. The fluid delivery module further has a first component for controlling flow and a substrate assembly. The first component for controlling flow has a first port, a second port, and a first flow path extending from the first port to the second port, the first flow path forming a first portion of the flow passage. The substrate assembly includes first and second end substrate blocks and a plurality of connector substrate blocks. Each of the first end substrate block has a first port and a first connector. Each of the plurality of connector substrate blocks has a first connector and a second connector. The first end substrate block is joined to a first one of the plurality of connector substrate blocks. The first connector of the first end substrate block engages the first connector of the first one of the plurality of connector substrate blocks. The second end substrate block is joined to a second one of the plurality of connector substrate blocks. The first connector of the second end substrate block engages the second connector of the second one of the plurality of connector substrate blocks. The first port of the first component is coupled to the first port of the first end substrate block of the substrate assembly so that the first flow path is fluidly coupled to the second flow path.

Further areas of applicability of the present technology will become apparent from the detailed description provided hereinafter. It should be understood that the detailed description and specific examples, while indicating the preferred implementation, are intended for purposes of illustration only and are not intended to limit the scope of the technology.

### BRIEF DESCRIPTION OF THE DRAWINGS

The invention of the present disclosure will become more fully understood from the detailed description and the accompanying drawings, wherein:

FIG. 1 is a schematic of a system for manufacturing semiconductor devices utilizing one or more apparatuses for controlling flow.

FIG. 2 is a perspective view of a fluid delivery module comprising at least one apparatus for controlling flow as may be utilized in the process of FIG. 1.

FIG. 3A is a perspective view of a component mounted to a substrate block and a substrate assembly as utilized in the fluid delivery module of FIG. 2.

FIG. 3B is a cross-sectional view of the component, substrate block, and the substrate assembly of FIG. 3A, taken along line 3B-3B.

FIG. 3C is a top view of the substrate block and substrate assembly of FIG. 3A.

FIG. 3D is a bottom view of the component of FIG. 3A.

FIG. 4 is a perspective view of the substrate assembly as utilized in the fluid delivery module of FIG. 2.

FIG. 5 is a cross-section view of the substrate assembly of FIG. 4.

FIG. 6 is a left view of the substrate assembly of FIG. 4.

FIG. 7 is a right view of the substrate assembly of FIG. 4.

FIG. 8A is a perspective view of a substrate block as may be used in the substrate assembly of FIG. 4, the substrate block having an end tee configuration.

FIG. 8B is a top view of the substrate block of FIG. 8A.

FIG. 8C is a front view of the substrate block of FIG. 8A.

FIG. 8D is a rear view of the substrate block of FIG. 8A.

FIG. 8E is a cross-sectional view of the substrate block of FIG. 8A, taken along line 8E-8E.

FIG. 8F is a cross-sectional view of the substrate block, taken along line 8F-8F of FIG. 8E.

FIG. 8G is a cross-sectional view of the substrate block, taken along line 8F-8F of FIG. 8E.

FIG. 9A is a perspective view of a substrate block as may be used in the substrate assembly of FIG. 4, the substrate block having an end left configuration.

FIG. 9B is a top view of the substrate block of FIG. 9A.

FIG. 9C is a front view of the substrate block of FIG. 9A.

FIG. 9D is a rear view of the substrate block of FIG. 9A.

FIG. 9E is a cross-sectional view of the substrate block of FIG. 9A, taken along line 9E-9E.

FIG. 9F is a cross-sectional view of the substrate block, taken along line 9F-9F of FIG. 9E.

FIG. 9G is a cross-sectional view of the substrate block, taken along line 9G-9G of FIG. 9E.

FIG. 10A is a perspective view of a substrate block as may be used in the substrate assembly of FIG. 4, the substrate block having an end right configuration.

FIG. 10B is a top view of the substrate block of FIG. 10A.

FIG. 10C is a front view of the substrate block of FIG. 10A.

FIG. 10D is a rear view of the substrate block of FIG. 10A.

FIG. 10E is a cross-sectional view of the substrate block of FIG. 10A, taken along line 10E-10E.

FIG. 10F is a cross-sectional view of the substrate block, taken along line 10F-10F of FIG. 10E.

FIG. 10G is a cross-sectional view of the substrate block, taken along line 10G-10G of FIG. 10E.

FIG. 11A is a perspective view of a substrate block as may be used in the substrate assembly of FIG. 4, the substrate block having an end tee inlet configuration.

FIG. 11B is a top view of the substrate block of FIG. 11A.

FIG. 11C is a front view of the substrate block of FIG. 11A.

FIG. 11D is a rear view of the substrate block of FIG. 11A.

FIG. 11E is a cross-sectional view of the substrate block of FIG. 11A, taken along line 33-33.

FIG. 11F is a cross-sectional view of the substrate block, taken along line 11F-11F of FIG. 11E.

FIG. 11G is a cross-sectional view of the substrate block, taken along line 11G-11G of FIG. 11E.

FIG. 12A is a perspective view of a substrate block as may be used in the substrate assembly of FIG. 4, the substrate block having an end left inlet configuration.

FIG. 12B is a top view of the substrate block of FIG. 12A.

FIG. 12C is a front view of the substrate block of FIG. 12A.

FIG. 12D is a rear view of the substrate block of FIG. 12A.

FIG. 12E is a cross-sectional view of the substrate block of FIG. 12A, taken along line 12E-12E.

FIG. 12F is a cross-sectional view of the substrate block, taken along line 12F-12F of FIG. 12E.

FIG. 12G is a cross-sectional view of the substrate block, taken along line 12G-12G of FIG. 12E.

FIG. 13A is a perspective view of a substrate block as may be used in the substrate assembly of FIG. 4, the substrate block having an end right inlet configuration.

FIG. 13B is a top view of the substrate block of FIG. 13A.

FIG. 13C is a front view of the substrate block of FIG. 13A.

FIG. 13D is a rear view of the substrate block of FIG. 13A.

FIG. 13E is a cross-sectional view of the substrate block of FIG. 13A, taken along line 13E-13E.

FIG. 13F is a cross-sectional view of the substrate block, taken along line 13F-13F of FIG. 13E.

FIG. 13G is a cross-sectional view of the substrate block, taken along line 13G-13G of FIG. 13E.

FIG. 14A is a perspective view of a substrate block as may be used in the substrate assembly of FIG. 4, the substrate block having a connector tee through configuration.

FIG. 14B is a top view of the substrate block of FIG. 14A.

FIG. 14C is a front view of the substrate block of FIG. 14A.

FIG. 14D is a rear view of the substrate block of FIG. 14A.

FIG. 14E is a cross-sectional view of the substrate block of FIG. 14A, taken along line 14E-14E.

FIG. 14F is a cross-sectional view of the substrate block, taken along line 14F-14F of FIG. 14E.

FIG. 14G is a cross-sectional view of the substrate block, taken along line 14G-14G of FIG. 14E.

FIG. 15A is a perspective view of a substrate block as may be used in the substrate assembly of FIG. 4, the substrate block having a connector left through configuration.

FIG. 15B is a top view of the substrate block of FIG. 15A.

FIG. 15C is a front view of the substrate block of FIG. 15A.

FIG. 15D is a rear view of the substrate block of FIG. 15A.

FIG. 15E is a cross-sectional view of the substrate block of FIG. 15A, taken along line 15E-15E.

FIG. 15F is a cross-sectional view of the substrate block, taken along line 15F-15F of FIG. 15E.

FIG. 15G is a cross-sectional view of the substrate block, taken along line 15G-15G of FIG. 15E.

FIG. 16A is a perspective view of a substrate block as may be used in the substrate assembly of FIG. 4, the substrate block having a connector right through configuration.

FIG. 16B is a top view of the substrate block of FIG. 16A.

FIG. 16C is a front view of the substrate block of FIG. 16A.

FIG. 16D is a rear view of the substrate block of FIG. 16A.

FIG. 16E is a cross-sectional view of the substrate block of FIG. 16A, taken along line 16E-16E.

FIG. 16F is a cross-sectional view of the substrate block, taken along line 16F-16F of FIG. 16E.

FIG. 16G is a cross-sectional view of the substrate block, taken along line 16G-16G of FIG. 16E.

FIG. 17A is a perspective view of a substrate block as may be used in the substrate assembly of FIG. 4, the substrate block having a connector tee blocking configuration.

FIG. 17B is a top view of the substrate block of FIG. 17A.

FIG. 17C is a front view of the substrate block of FIG. 17A.

FIG. 17D is a rear view of the substrate block of FIG. 17A.

FIG. 17E is a cross-sectional view of the substrate block of FIG. 17A, taken along line 17E-17E.

FIG. 17F is a cross-sectional view of the substrate block, taken along line 17F-17F of FIG. 17E.

FIG. 17G is a cross-sectional view of the substrate block, taken along line 17G-17G of FIG. 17E.

FIG. 18A is a perspective view of a substrate block as may be used in the substrate assembly of FIG. 4, the substrate block having a connector double tee configuration.

FIG. 18B is a top view of the substrate block of FIG. 18A.

FIG. 18C is a front view of the substrate block of FIG. 18A.

FIG. 18D is a rear view of the substrate block of FIG. 18A.

FIG. 18E is a cross-sectional view of the substrate block of FIG. 18A, taken along line 18E-18E.

FIG. 18F is a cross-sectional view of the substrate block, taken along line 18F-18F of FIG. 18E.

FIG. 18G is a cross-sectional view of the substrate block, taken along line 18G-18G of FIG. 18E.

FIG. 19A is a perspective view of a substrate block as may be used in the substrate assembly of FIG. 4, the substrate block having a spacer configuration.

FIG. 19B is a top view of the substrate block of FIG. 19A.

FIG. 19C is a front view of the substrate block of FIG. 19A.

FIG. 19D is a rear view of the substrate block of FIG. 19A.

FIG. 19E is a cross-sectional view of the substrate block of FIG. 19A, taken along line 19E-19E.

FIG. 19F is a cross-sectional view of the substrate block, taken along line 19F-19F of FIG. 19E.

FIG. 19G is a cross-sectional view of the substrate block, taken along line 19G-19G of FIG. 19E.

All drawings are schematic and not necessarily to scale. Features shown numbered in certain figures which may appear un-numbered in other figures are the same features unless noted otherwise herein.

### DETAILED DESCRIPTION

The description of illustrative embodiments according to principles of the present invention is intended to be read in connection with the accompanying drawings, which are to be considered part of the entire written description. In the description of embodiments of the invention disclosed herein, any reference to direction or orientation is merely intended for convenience of description and is not intended in any way to limit the scope of the present invention. Relative terms such as “lower,” “upper,” “horizontal,” “vertical,” “above,” “below,” “up,” “down,” “left,” “right,” “top” and “bottom” as well as derivatives thereof (e.g., “horizontally,” “downwardly,” “upwardly,” etc.) should be construed to refer to the orientation as then described or as shown in the drawing under discussion. These relative terms are for convenience of description only and do not require that the apparatus be constructed or operated in a particular orientation unless explicitly indicated as such. Terms such as “attached,” “affixed,” “connected,” “coupled,” “interconnected,” and similar refer to a relationship wherein structures are secured or attached to one another either directly or indirectly through intervening structures, as well as both movable or rigid attachments or relationships, unless expressly described otherwise. Moreover, the features and benefits of the invention are illustrated by reference to the preferred embodiments. Accordingly, the invention expressly should not be limited to such preferred embodiments illustrating some possible non-limiting combinations of features that may exist alone or in other combinations of features; the scope of the invention being defined by the claims appended hereto.

The present invention is directed to a fitting assembly for use in a fluid delivery module comprising at least one apparatus for controlling fluid flow. In some embodiments, the fluid delivery module may include a mass flow controller to deliver a known mass flow of fluid to a semiconductor process or similar process. Semiconductor fabrication is one industry which demands high performance in control of fluid flows. As semiconductor fabrication techniques have advanced, customers have recognized the need for flow control devices with increased complexity and capability. Modern semiconductor processes require that the cost of the fluid delivery modules is reduced and parts interchangeability is maximized. The present invention provides for a modular fitting assembly which can be utilized in a variety of applications within the fluid delivery module.

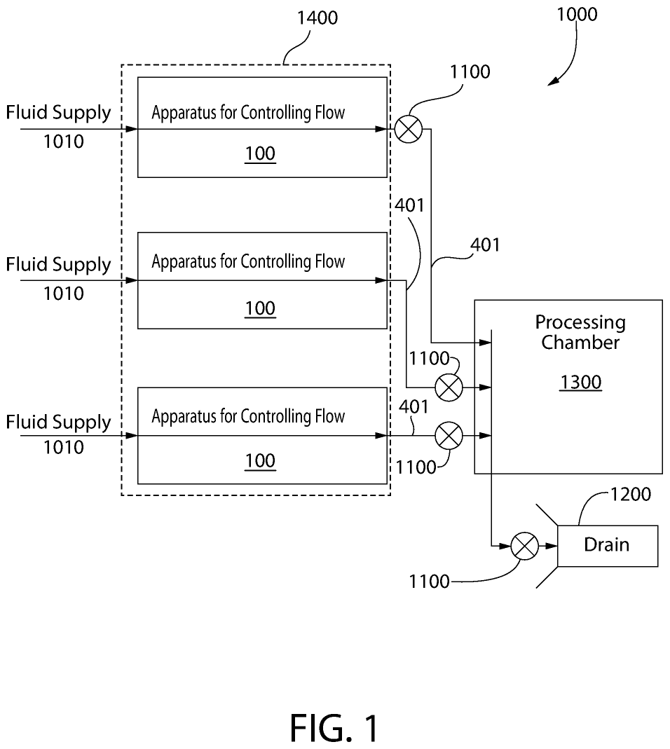

FIG. 1 shows a schematic of an exemplary processing system 1000. The processing system 1000 may utilize one or more apparatus for controlling flow 100 fluidly coupled to a processing chamber 1300. The apparatus for controlling flow 100 are used to supply one or more different process fluids to the processing chamber 1300. Fluids are provided by a plurality of fluid supplies, or fluid sources. Collectively, the plurality of apparatus for controlling flow 100 belong to a fluid delivery module 1400. Optionally, more than one fluid delivery module 1400 may be utilized in the processing system 100. The plurality of apparatus for controlling flow 100 are connected to the processing chamber 1300 by an outlet manifold 400. Articles such as semiconductors and integrated circuits may be processed within the processing chamber 1300.

Valves 1100 isolate each of the apparatus for controlling flow 100 from the processing chamber 1300, enabling each of the apparatus for controlling flow 100 to be selectively connected or isolated from the processing chamber 1300, facilitating a wide variety of different processing steps. The processing chamber 1300 may contain an applicator to apply process fluids delivered by the plurality of apparatus for controlling flow 100, enabling selective or diffuse distribution of the fluids supplied by the plurality of apparatus for controlling flow 100. Optionally, the processing chamber 1300 may be a vacuum chamber or may be a tank or bath for immersing articles in the fluids supplied by the plurality of apparatus for controlling flow 100. A fluid supply line is formed by the flow path from each of the respective fluid supplies to the processing chamber 1300.

In addition, the processing system 1000 may further comprise a drain 1200 which is isolated from the processing chamber 1300 by a valve 1100 to enable evacuation of process fluids or facilitate purging one or more of the apparatus for controlling flow 100 to enable switching between process fluids in the same apparatus for controlling flow 100. Optionally, the drain 1200 may be a source of vacuum or may be a liquid drain configured to remove liquids from the processing chamber 1300. Optionally, the apparatus for controlling flow 100 may be mass flow controllers, flow splitters, or any other device which controls the flow of a process fluid in a processing system. Furthermore, the valves 1100 may be integrated into the apparatus for controlling flow 100 if so desired.

Processes that may be performed in the processing system 1000 may include wet cleaning, photolithography, ion implantation, dry etching, atomic layer etching, wet etching, plasma ashing, rapid thermal annealing, furnace annealing, thermal oxidation, chemical vapor deposition, atomic layer deposition, physical vapor deposition, molecular beam epitaxy, laser lift-off, electrochemical deposition, chemical-mechanical polishing, wafer testing, electroplating, or any other process utilizing fluids.

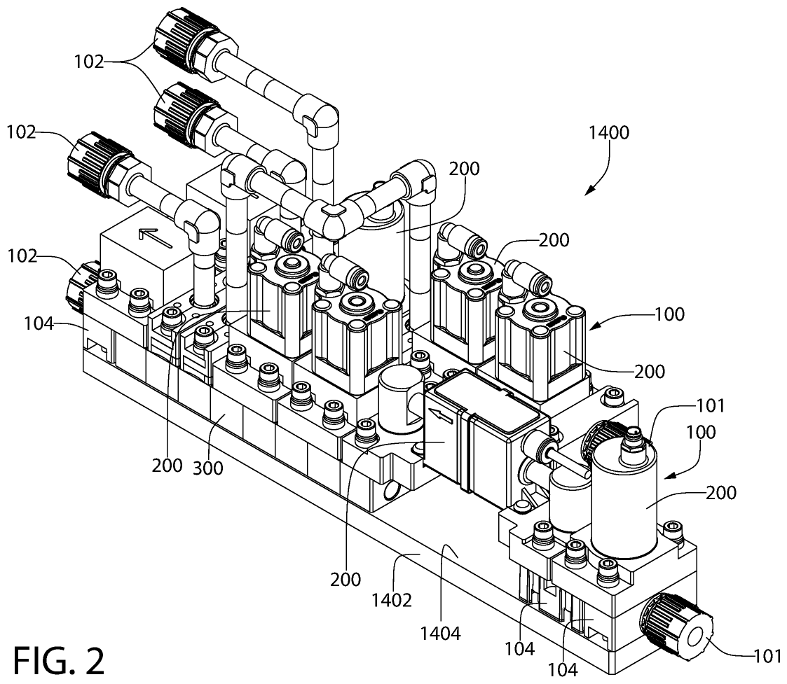

FIG. 2 shows a schematic of an exemplary fluid delivery module 1400. In this embodiment, the fluid delivery module 1400 has a plurality of apparatus for controlling flow 100 having a plurality of inlets 101 and a plurality of outlets 102. In some embodiments, the plurality of inlets 101 do not correspond to the plurality of outlets 102 in a one to one manner. Instead, a plurality of inlets 101 may be joined into a single outlet 102 and a single inlet 101 may be split into a plurality of outlets 102. This may be done to achieve mixing or combination of different fluids prior to providing them to the process chamber 1300. Nonetheless, at least one flow passage extends from one of the inlets 101 to one of the outlets 102, the flow passage being formed by the various components of the fluid delivery module 1400.

As can be seen, each of the apparatus for controlling flow 100 is arranged generally in a row, with the plurality of apparatus 100 in parallel rows. This need not be the case, and any packaging configuration may be used. The fluid delivery module 1400 has a substrate panel 1402. The substrate panel 1402 serves as support structure for the fluid delivery module 1400, but it may be simply used to facilitate assembly. Other structural support configurations are contemplated. One or more substrate blocks 104 and a substrate assembly 300 are in direct surface contact with an upper surface 1404 of the substrate panel 1402. The substrate blocks 104 and the substrate assembly 300 comprise fluid ports therein to conduct flow to one or more fluid flow components 200 having corresponding fluid ports as discussed in greater detail below. The fluid flow components 200 may be considered active components while the substrate blocks 104 and the substrate assembly 300 may be considered passive components. The fluid flow components 200 may be one or more of a valve, a flow controller, a pressure transducer, a flow measurement sensor, a pressure regulator, a flow restrictor, an actuator, an inlet 101 or outlet 102, or any other known flow control component. A plurality of anchors are used to couple the fluid flow components 200 to the substrate blocks 104 and the substrate assembly 300. The anchors may be threaded inserts or threads in the substrate blocks 104 or substrate assembly 300, threaded inserts or threads in the substrate panel 1402, nuts, or other anchoring features which permit secure fastening of the fluid flow components 200.

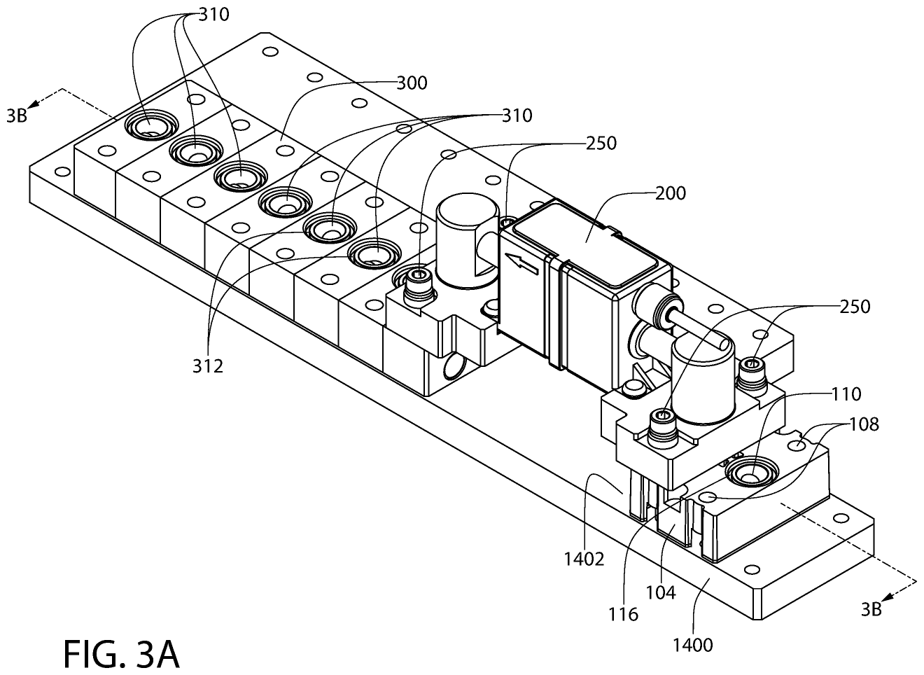

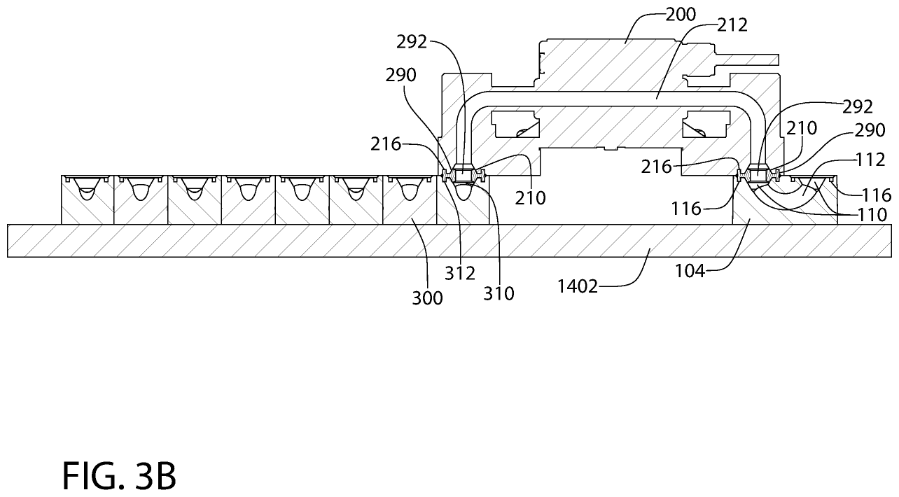

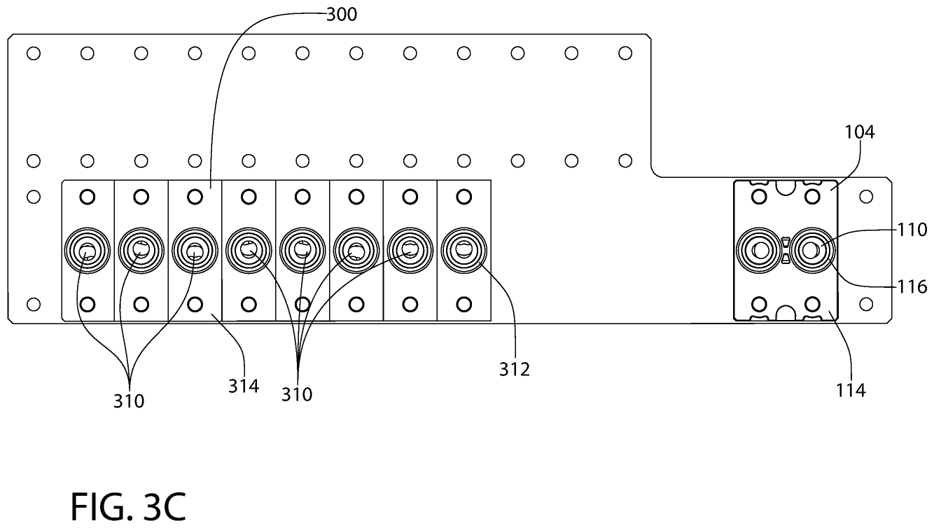

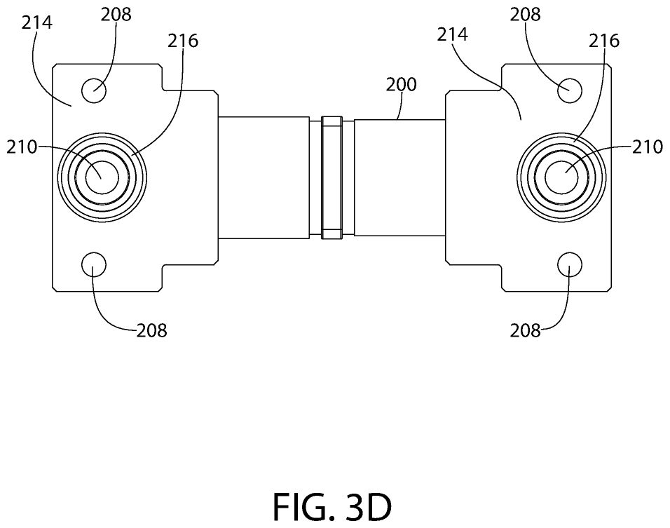

Turning to FIGS. 3A-D, a portion of the fluid delivery module 1400 is shown. Specifically, a fluid flow component 200 is shown mounted to a substrate block 104 and to the substrate assembly 300. The fluid flow component 200 is mounted to the substrate block 104 and the substrate assembly 300 via fasteners 250. The fasteners 250 may be used for alignment as well as for fastening and may be replaced by any suitable type of fastener capable of fastening the fluid flow components 200 to the substrate blocks 104. The fasteners 250 may be fasteners such as bolts, screws, pins, or other known fastening device. However, in other embodiments, the fasteners 250 may be separate from the alignment features. For instance, dowel pins or other pins may be used to align the fluid flow component 200 to the substrate block 104 and substrate assembly 300. Then, a separate component fastener may be used for fastening the fluid flow component 200 to the substrate block 104 and substrate assembly 300. Preferably, the fasteners 250 extend through the substrate block 104 and the substrate assembly 300 to engage the substrate panel 1402. In other implementations, there may be fasteners 250 which couple the substrate blocks 104 and substrate assembly 300 to the substrate panel 1402 while additional fasteners 250 couple the component 200 to the substrate block 104 and substrate assembly 300.

Although not shown in FIGS. 3A-D, the substrate panel 1402 has anchors. The anchors comprise portions of the substrate panel 1402 which are threaded or have threaded inserts which receive the fasteners 250. Thus, the fasteners 250 extend through fastener passageways 208 in the fluid flow component 200, fastener passageways 108 in the substrate blocks 104, and install into anchors in the substrate panel 1402. The fasteners 250 are intended for rough alignment, but precision alignment is provided by other geometry. Thus, the fastener passageways 108, 208 need not be a precision fit on the fasteners 250. In alternate embodiments, the fasteners 250 may install directly to the substrate blocks 104 via threaded holes or inserts within the fastener passageways 108. In these embodiments, the substrate blocks 104 may be separately attached to the substrate panel 1402 via additional fasteners. In other embodiments, the fasteners 250 may install into supports or other components which are beneath the substrate panel 1402.

The substrate blocks 104 need not be identical. Some substrate blocks 104 have a single fluid port while other substrate blocks 104 have two fluid ports. Substrate blocks 104 with a single fluid port may receive a single component 200 and may also incorporate a tube or other feature which is configured to allow passage of fluid. Substrate blocks 104 which have two fluid ports may receive two separate components 200. The substrate assembly 300 may also incorporate one or more fluid ports. Preferably, the substrate assembly 300 has a plurality of fluid ports to permit coupling of a plurality of components 200.

As best shown in FIG. 3B, an annular seal 290 is positioned between the fluid flow component 200 and the substrate block 104. Similarly, another annular seal 290 is positioned between the fluid flow component 200 and the substrate assembly 300. The seal 290 has a flow path 292 through the center which permits passage of fluid therethrough. The seal 290 provides a hermetic seal between a fluid port 210 of the fluid flow component 200 and a fluid port 310 of the substrate assembly 300. The fluid port 310 of the substrate assembly 300 comprises a seal cavity 312. Each of the fluid ports 210 of the fluid flow component 200 comprises a seal cavity 216. Similarly, the second substrate block 104 has two fluid ports 110 comprising seal cavities 116. The seal 290 is positioned within the seal cavity 312 of the substrate assembly 300 and within the seal cavity 216 of the fluid flow component 200. Similarly, a second seal 290 is positioned between the other seal cavity 216 of the fluid flow component 200 and the seal cavity 116 of the second substrate block 104. A fluid flow path 212 extends through the component 200 from the first port 210 to the second port 210.

FIG. 3C shows the substrate assembly 300 and the substrate block 104 as viewed from above. As discussed above, the substrate assembly 300 has a plurality of fluid ports 310 while the second substrate block 104 has two fluid ports 110. Seals 290 may be inserted into seal cavities 116, 312 to seal with components 200 mounted to the substrate assembly 300 and the substrate block 104. The substrate assembly 300 comprises a seal side mounting surface 314. The substrate block 104 also comprises a seal side mounting surface 114. The seal side mounting surfaces 314, 114 are the side which receives the seal 290 in a seal cavity 312, 116. As will be discussed in greater detail below, the seal side mounting surface 314 is formed by surfaces of a plurality of substrate blocks which make up the substrate assembly 300. These substrate blocks will be discussed in greater detail below and are distinct from the substrate blocks 104 which are separate from the substrate assembly 300. In contrast, the substrate block 104 is formed as a single component and an entirety of the seal side mounting surface 114 is formed by the second substrate block 104. Thus, except for the port 110, the seal side mounting surface 114 is substantially planar. A fluid flow path 112 extends through the second substrate block 104 from the first port 110 to the second port 110.

Turning to FIG. 3D, the fluid flow component 200 comprises a seal side mounting surface 214 comprising two fluid ports 210, with one fluid port 210 being an inlet and the other being an outlet. As discussed above, a fluid flow path 212 extends from a fluid opening of one fluid port 210 to a fluid opening of the other fluid port 210. The seal 290 is compressed between the fluid flow component 200 and the substrate assembly 300 or substrate block 104. During assembly, the seal side mounting surfaces 114, 214, 314 are drawn closer together by the fasteners 250, reducing the distance between the seal side mounting surfaces 114, 314 of the substrate assembly 300 and the substrate block 104 and the seal side mounting surface 214 of the fluid flow component 200. Optionally, the seal side mounting surface 214 may be spaced from the seal side mounting surfaces 114, 314 of the substrate assembly and the substrate block 104 or the seal side mounting surface 214 may be in contact with the seal side mounting surfaces 114, 314.

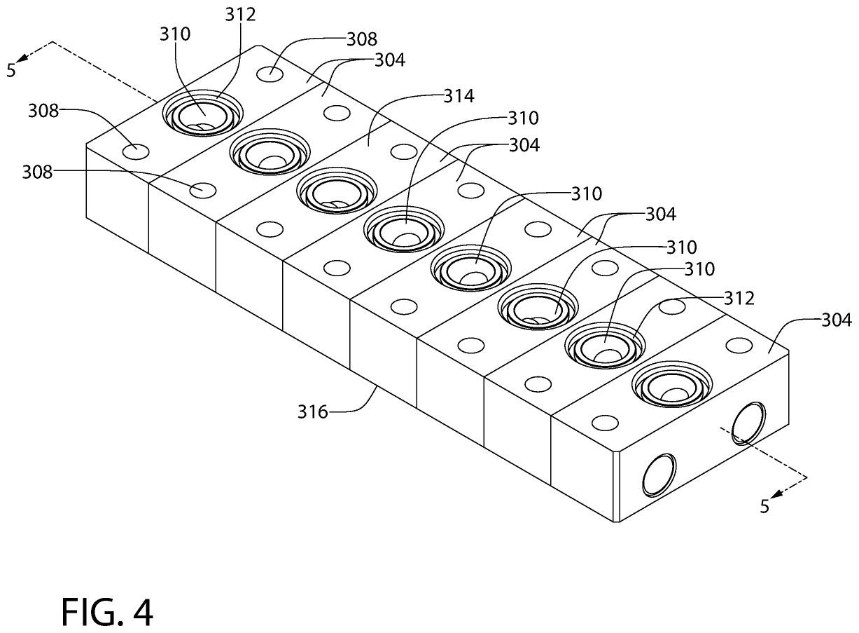

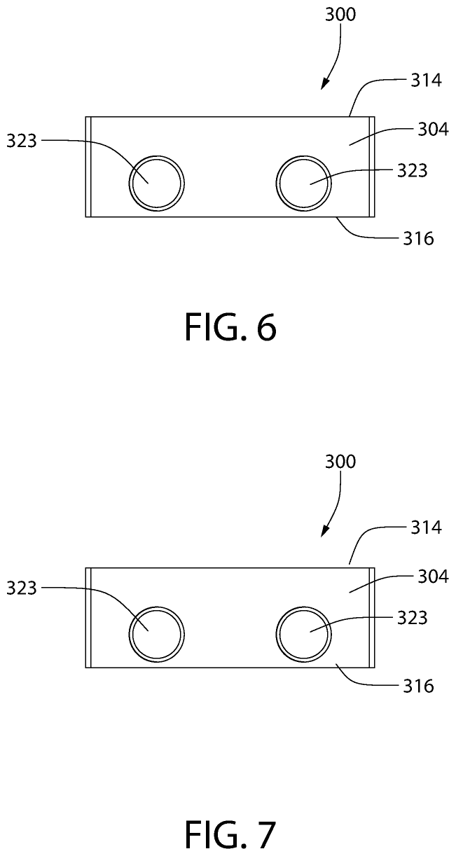

Turning to FIGS. 4 to 7, the substrate assembly 300 is illustrated in greater detail. The substrate assembly 300 is formed of a plurality of substrate blocks 304. The substrate blocks 304 may be a variety of different types, allowing flexible configuration of fluid flow. Optionally, some or all of the substrate blocks 304 may comprise fluid ports 310, each fluid port 310 having a seal cavity 312 to receive a seal 290 as discussed above. Optionally, some of the substrate blocks 304 may be free of fluid ports 310. The substrate blocks 304 may also comprise fastener passageways 308 similar to the fastener passageways 108, 208 of the substrate blocks 104 and components 200. The fastener passageways 308 may allow mounting of components 200 to the substrate assembly 300 via fasteners 250 which engage the substrate blocks 304 of the substrate assembly 300 or the substrate panel 1402 in the same manner discussed above. The substrate blocks 304 may have one, two, or no fastener passageways 308 as desired. In the present embodiment, the fastener passageways 308 extend through the substrate blocks 304, but in some implementations they may extend only a portion of the thickness of the substrate blocks 304.

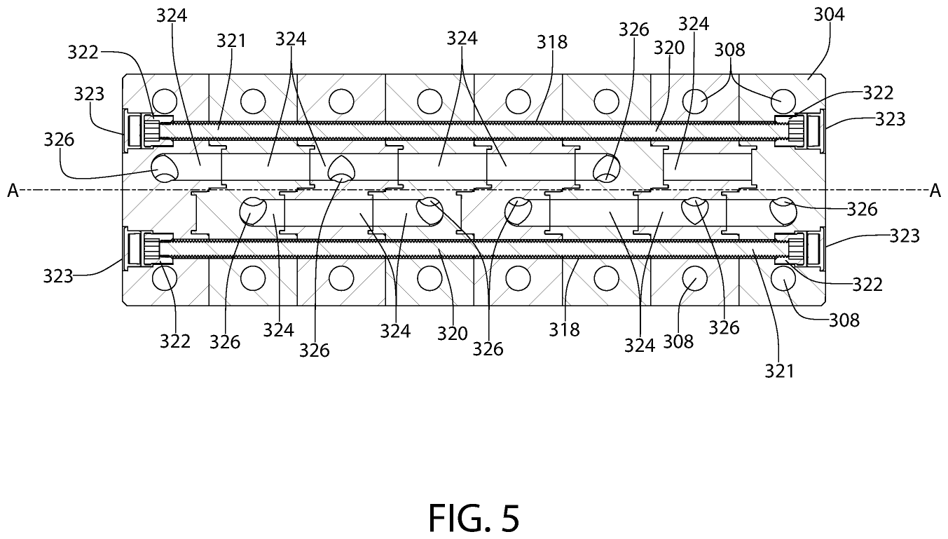

The substrate assembly 300 has a seal side mounting surface 314 and an opposite bottom surface 316. The seal side mounting surface 314 receives the seals 290 and components 200. The bottom surface 316 is in direct surface contact with the upper surface 1404 of the substrate panel 1402. The substrate blocks 304 of the substrate assembly 300 are coupled together via a plurality of coupling holes 318 which extend parallel to a longitudinal axis A-A as best seen in FIG. 5. First and second fasteners 320 extend through the coupling holes 318.

The fasteners 320 may comprise a threaded rod 321 and nuts 322 or may comprise a bolt and nut combination. In yet other configurations, the fasteners 320 may be any configuration required to apply a compression force to the substrate blocks 304 to ensure that they are not able to be readily separated during installation and assembly. A plurality of covers 323 seal the fasteners 320 within the substrate blocks 304. The covers 323 may be retained via a snap fit, adhesive, press fit, or any other known technique and may be fluid tight to prevent entry of gases or liquids.

The substrate assembly 300 comprises a plurality of channels 324 which extend parallel to the longitudinal axis A-A. The channels 324 may extend through the substrate blocks 304 or may only extend through a portion of the substrate blocks 304 as illustrated. The channels 324 may intersect passages 326, the passages 326 extending from the channels 324 to the fluid ports 310. Thus, the passages 326 may create a flow path between the fluid ports 310 and the channels 324. Optionally, each of the substrate blocks 304 may have one, two, or more channels 324. Similarly, each of the substrate blocks 304 may have one, two, or more passages 326. Alternately, each of the substrate blocks 304 may have no channels 324 or passages 326 if so desired. As can be seen, the substrate blocks 304 may be differently configured to permit any desired routing of a fluid flow path. In some configurations, the channels 324 may not connect to a passage 326 or connect to another channel 324 and may not form a portion of a fluid flow path. Each of the substrate blocks 304 have a length measured along the longitudinal axis A-A. Optionally, all of the substrate blocks 304 may have the same length or one or more substrate blocks 304 may have a different length. Optionally, all of the substrate blocks 304 except one has the same length while only one substrate block 304 may have a greater length than the lengths of the other substrate blocks 304.

In yet other configurations, the components 200 may also serve as one or more substrate blocks 304. Thus, where high density packaging is required, components 200 may incorporate the required connector structure to enable the components 200 to serve as substrate blocks 304. Similarly, components 200 may also incorporate additional flow passages which enable routing of fluid in the delivery module 1400. These components 200 may be mounted on the substrate assembly 300 or form a part of the substrate assembly 300. Thus, the substrate assembly 300 serves as a first layer while the components 200 may serve as a second layer. In yet other implementations, additional components 200 may be stacked onto components of the second layer to form a three layer routing of fluid flow paths. This may be particularly desirable to increase routing density where space for the fluid delivery module 1400 is constrained.

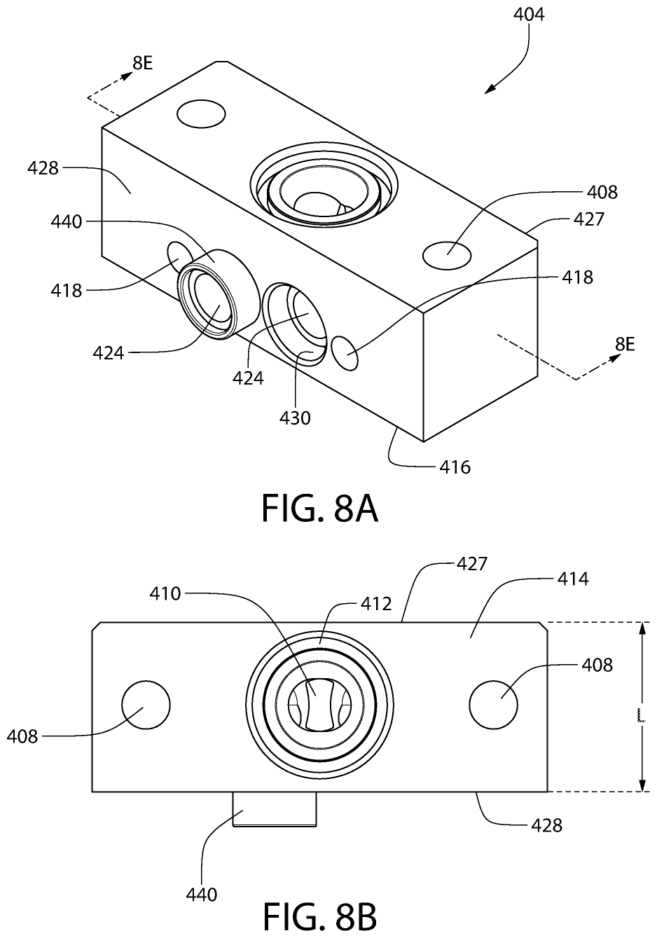

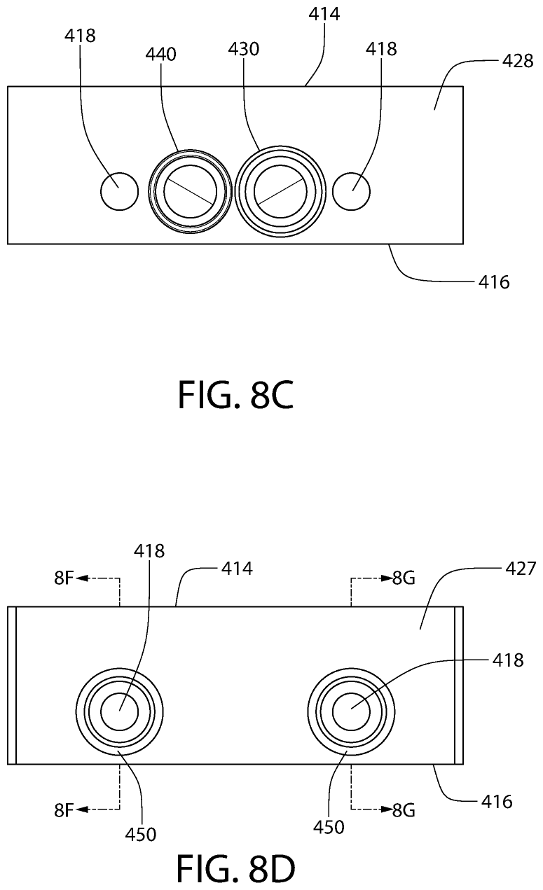

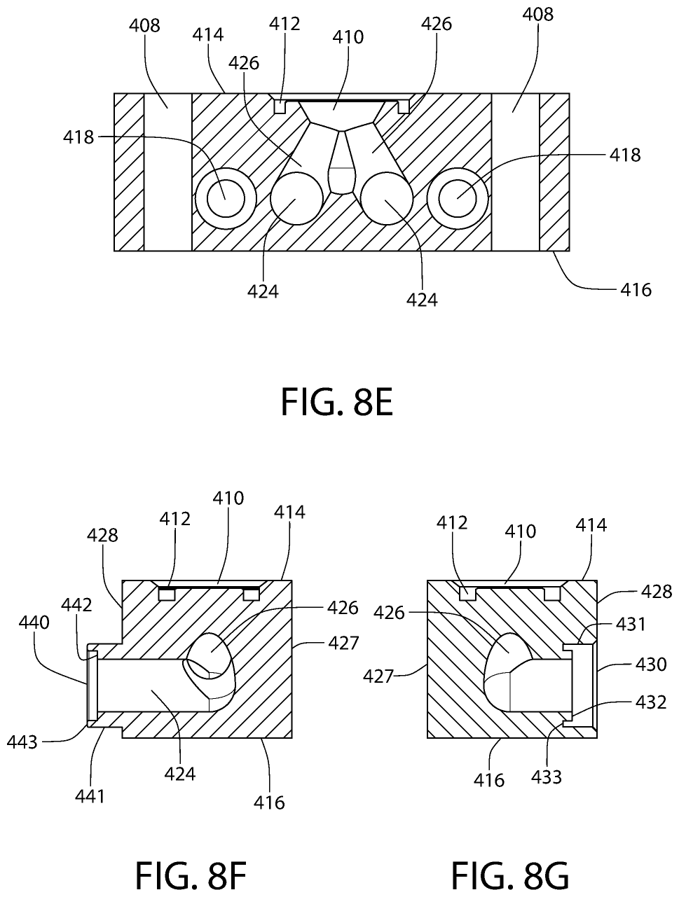

Turning to FIGS. 8A-8G, a substrate block 404 is illustrated. The substrate block 404 has an end tee configuration and may be utilized in the substrate assembly 300 described above. The substrate block 404 may be utilized as an end substrate block in the substrate assembly 300 as will be discussed in greater detail below. The substrate block 404 has a fluid port 410, the fluid port 410 having a seal cavity 412. The fluid port 412 is formed into a seal side mounting surface 414. Fastener passageways 408 are also formed into the seal side mounting surface 414 and extend through the substrate block 404. A bottom surface 416 is opposite the seal side mounting surface 414.

The substrate block 404 also has an end surface 427 and an opposite mating surface 428. The substrate block 404 has a length L measured from the end surface 427 to the mating surface 428. Coupling holes 418 extend from the end surface 427 to the mating surface 428 to allow passage of the fasteners 320 as described above. The mating surface 428 also has a female connector 430 and a male connector 440. The female connector 430 has a cylindrical cavity 431 formed into the mating surface 428. The cylindrical cavity 431 terminates in a floor 432. An annular groove 433 is formed into the floor 432. Optionally, the annular groove 433 may have an outer diameter equal to a diameter of the cylindrical cavity 431 or may have an outer diameter which is less than a diameter of the cylindrical cavity 431. A channel 424 extends from the floor 432 of the female connector 430 to a passage 426, the passage 426 extending from the channel 424 to the fluid port 410.

The male connector 440 has a cylindrical protuberance 441 extending from the mating surface 428. The cylindrical protuberance 441 terminates in a distal end 442. An annular ring 443 extends from the distal end 442. Optionally, the annular ring 443 may have an outer diameter which is equal to a diameter of the cylindrical protuberance 441 or the outer diameter of the annular ring 443 may be less than a diameter of the cylindrical protuberance 441. A channel 424 extends from a passage 426 to the distal end 442 of the cylindrical protuberance 441 of the male connector 440. The annular ring 443 also has an inner diameter which is greater than a diameter of the channel 424 such that the distal end 442 of the cylindrical protuberance 441 forms an end surface of the cylindrical protuberance 441 and the annular ring 443 protrudes from the end surface. The passage 426 extends from the channel 424 to the fluid port 410.

The male connector 440 is configured to couple to a female connector of another substrate block 304 and provide a fluid-tight connection between the male and female connectors. Similarly, the female connector 430 is configured to couple to a male connector of another substrate block 304 and provide a fluid-tight connection between the male and female connectors. The male connectors 440 are configured to interface with any of the female connectors of the substrate blocks 304 and vice versa. This may be achieved by a close fit or interference fit between the respective surfaces. For example, a seal may be achieved by the outer diameter of the annular ring 443 or the diameter of the cylindrical protuberance 441 being greater than the diameter of the cylindrical cavity 430 or the outer diameter of the annular groove 433. Similarly, the inner diameter of the annular ring 443 may be less than the inner diameter of the annular groove 433. In other configurations, the end surface of the annular ring 443 may be configured to form a seal with a bottom surface of the annular ring 443. In yet other configurations, the distal end 442 of the cylindrical protuberance 441 may form a seal with the floor 432 of the female connector 430. The fasteners 320 may be used to compress the substrate blocks 304 and ensure that the male and female connectors remain mated. Other mating geometries are contemplated, with the goal of any connector geometry being to provide a fluid-tight connection between substrate blocks 304 within the substrate assembly 300. As can be seen, the end tee configuration of the substrate block 404 has a common connection between the male connector 440, the female connector 430, and the fluid port 410 thanks to the channels 424 and passages 426.

Two fastener cavities 450 are provided in the end surface 427. The fastener cavities 450 may be formed as stepped counter bores which are configured to receive both the nuts 322 and covers 323 or to receive the head of a bolt and a cover 323. The fastener cavities 450 are configured to ensure that both the nuts 322 and the cover 323 are recessed with respect to the end surface 427. No analogous fastener cavities 450 are formed in the mating surface 428 because the mating surface 428 is configured to allow mating of the substrate block 404 with another substrate block 304 while the end surface 427 forms an end surface of the substrate assembly 300.

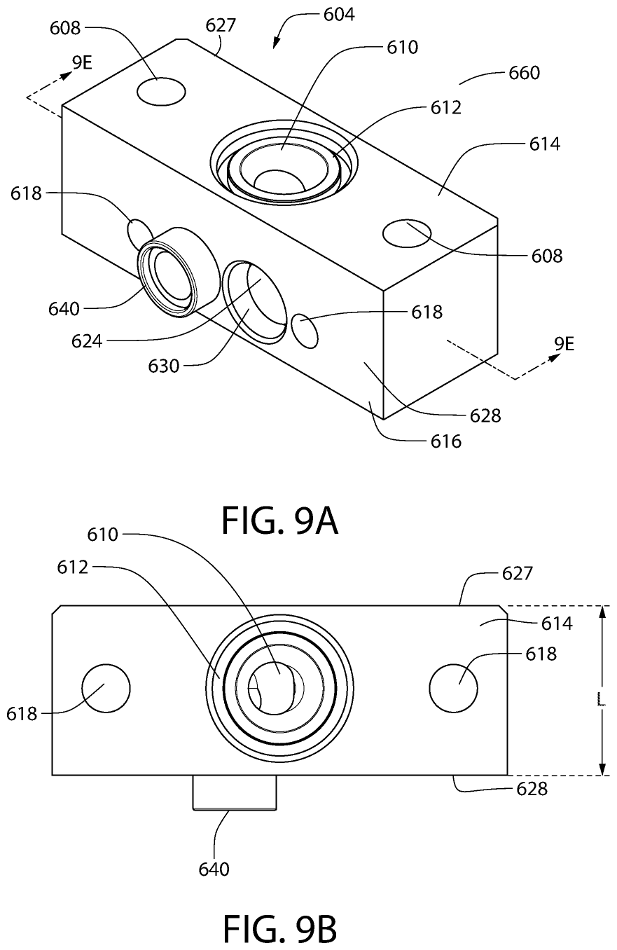

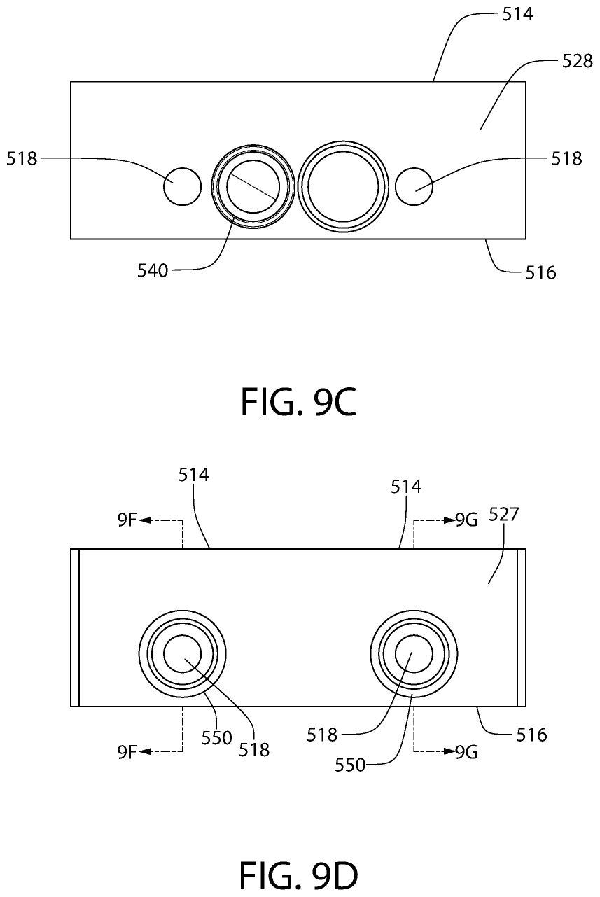

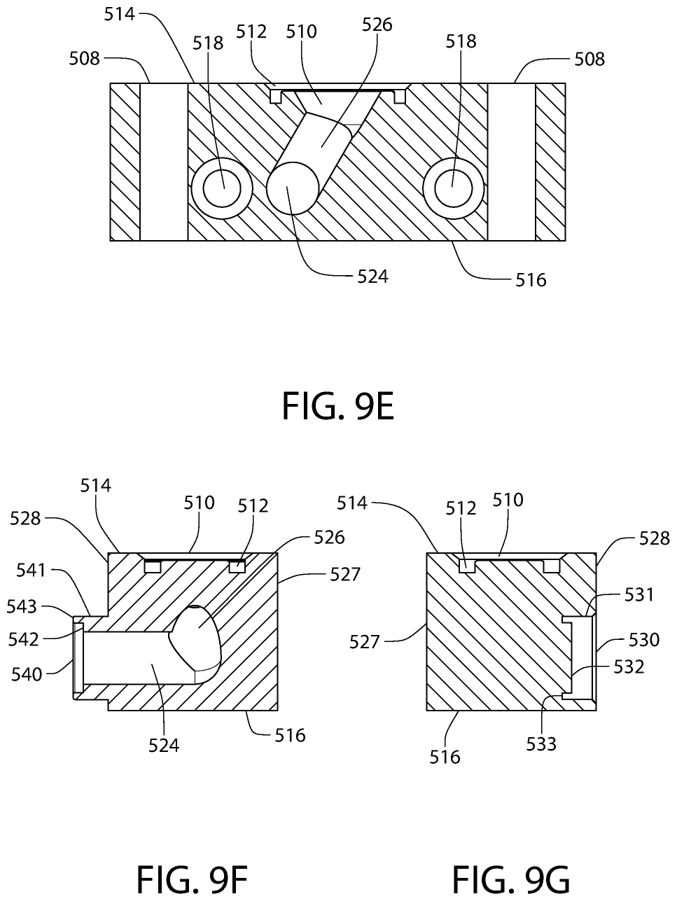

Turning to FIGS. 9A-G, a substrate block 504 is illustrated. The substrate block 504 has an end left configuration and may be utilized in the substrate assembly 300 described above. The substrate block 504 may be utilized as an end substrate block in the substrate assembly 300 as will be discussed in greater detail below. The substrate block 504 has a fluid port 510, the fluid port 510 having a seal cavity 512. The fluid port 512 is formed into a seal side mounting surface 514. Fastener passageways 508 are also formed into the seal side mounting surface 514 and extend through the substrate block 504. A bottom surface 516 is opposite the seal side mounting surface 514.

The substrate block 504 also has an end surface 527 and an opposite mating surface 528. The substrate block 504 has a length L measured from the end surface 527 to the mating surface 528. Coupling holes 518 extend from the end surface 527 to the mating surface 528 to allow passage of the fasteners 320 as described above. The mating surface 528 also has a female connector 530 and a male connector 540. The female connector 530 has a cylindrical cavity 531 formed into the mating surface 528. The cylindrical cavity 531 terminates in a floor 532. An annular groove 533 is formed into the floor 532. Optionally, the annular groove 533 may have an outer diameter equal to a diameter of the cylindrical cavity 531 or may have an outer diameter which is less than a diameter of the cylindrical cavity 531. In contrast with the substrate block 404, no channel extends from the floor 532 of the female connector 530.

The male connector 540 has a cylindrical protuberance 541 extending from the mating surface 528. The cylindrical protuberance 541 terminates in a distal end 542. An annular ring 543 extends from the distal end 542. Optionally, the annular ring 543 may have an outer diameter which is equal to a diameter of the cylindrical protuberance 541 or the outer diameter of the annular ring 543 may be less than a diameter of the cylindrical protuberance 541. A channel 524 extends from a passage 526 to the distal end 542 of the cylindrical protuberance 541 of the male connector 540. The annular ring 543 also has an inner diameter which is greater than a diameter of the channel 524 such that the distal end 542 of the cylindrical protuberance 541 forms an end surface of the cylindrical protuberance 541 and the annular ring 543 protrudes from the end surface. The passage 526 extends from the channel 524 to the fluid port 510.

The male connector 540 is configured to couple to a female connector of another substrate block 304 and provide a fluid-tight connection between the male and female connectors. Similarly, the female connector 530 is configured to couple to a male connector of another substrate block 304 and provide a fluid-tight connection between the male and female connectors. The male connectors 540 are configured to interface with any of the female connectors of the substrate blocks 304 and vice versa. This may be achieved by a close fit or interference fit between the respective surfaces. For example, a seal may be achieved by the outer diameter of the annular ring 543 or the diameter of the cylindrical protuberance 541 being greater than the diameter of the cylindrical cavity 530 or the outer diameter of the annular groove 533. Similarly, the inner diameter of the annular ring 543 may be less than the inner diameter of the annular groove 533. In other configurations, the end surface of the annular ring 543 may be configured to form a seal with a bottom surface of the annular ring 543. In yet other configurations, the distal end 542 of the cylindrical protuberance 541 may form a seal with the floor 532 of the female connector 530. The fasteners 320 may be used to compress the substrate blocks 304 and ensure that the male and female connectors remain mated. Other mating geometries are contemplated, with the goal of any connector geometry being to provide a fluid-tight connection between substrate blocks 304 within the substrate assembly 300. As can be seen, the end left configuration of the substrate block 504 has a single flow path extending from the fluid port 510 to the male connector 540. The flow path extends from the fluid port 510 via the passage 526 and the channel 524 to the male connector 540. The female connector 530 is fluidly isolated from the fluid port 510.

Two fastener cavities 550 are provided in the end surface 527. The fastener cavities 550 may be formed as stepped counter bores which are configured to receive both the nuts 322 and covers 323 or to receive the head of a bolt and a cover 323. The fastener cavities 550 are configured to ensure that both the nuts 322 and the cover 323 are recessed with respect to the end surface 527. No analogous fastener cavities 550 are formed in the mating surface 528 because the mating surface 528 is configured to allow mating of the substrate block 504 with another substrate block 304 while the end surface 527 forms an end surface of the substrate assembly 300.

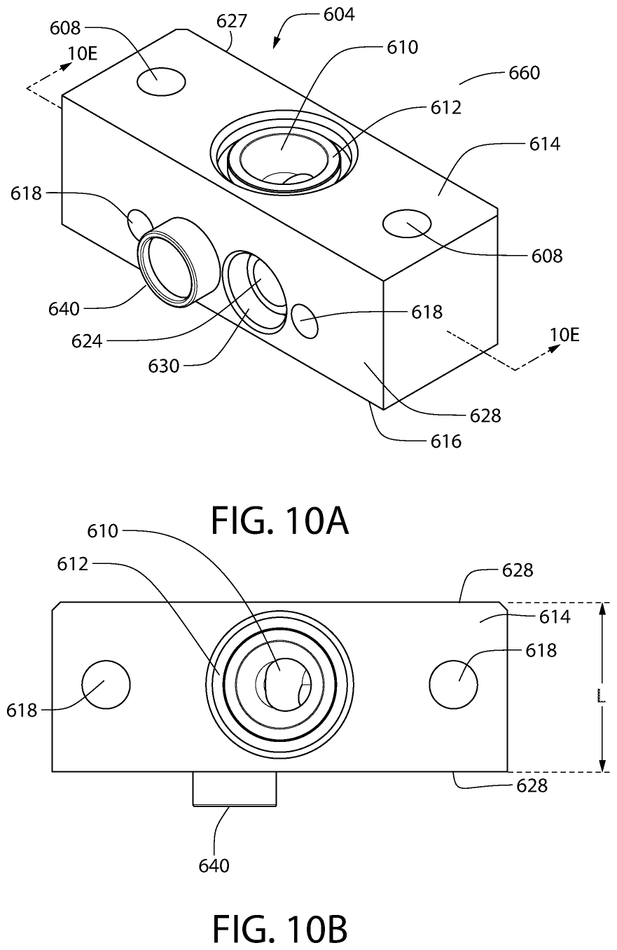

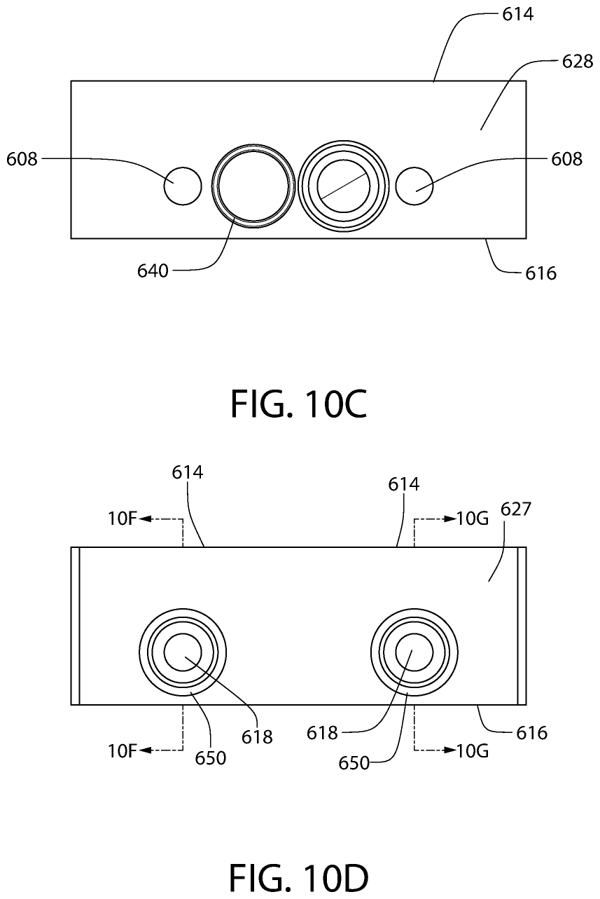

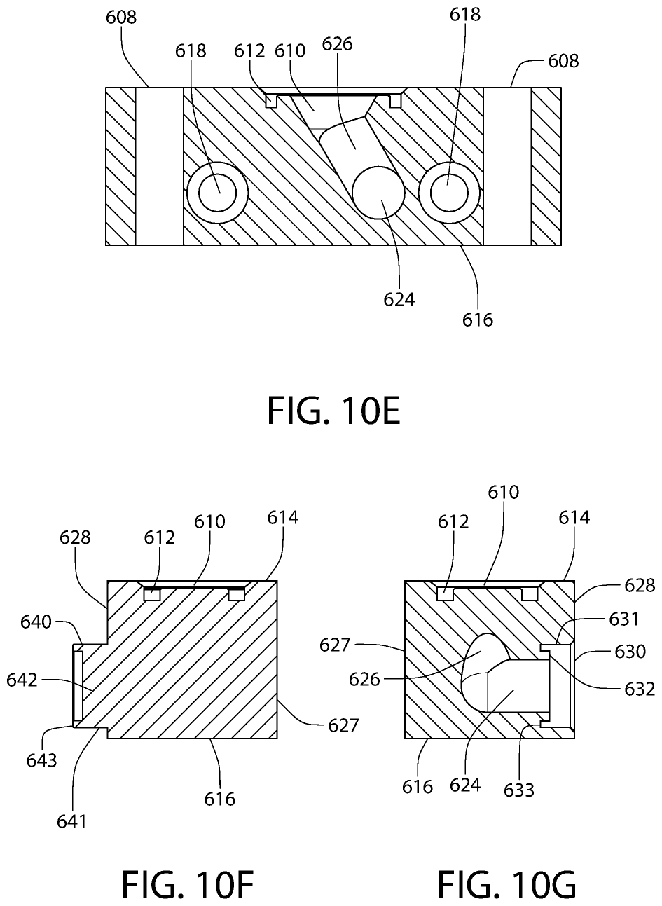

Turning to FIGS. 10A-G, a substrate block 604 is illustrated. The substrate block 604 has an end right configuration and may be utilized in the substrate assembly 300 described above. The substrate block 604 may be utilized as an end substrate block in the substrate assembly 300 as will be discussed in greater detail below. The substrate block 604 has a fluid port 610, the fluid port 610 having a seal cavity 612. The fluid port 612 is formed into a seal side mounting surface 614. Fastener passageways 608 are also formed into the seal side mounting surface 614 and extend through the substrate block 604. A bottom surface 616 is opposite the seal side mounting surface 614.

The substrate block 604 also has an end surface 627 and an opposite mating surface 628. The substrate block 604 has a length L measured from the end surface 627 to the mating surface 628. Coupling holes 618 extend from the end surface 627 to the mating surface 628 to allow passage of the fasteners 320 as described above. The mating surface 628 also has a female connector 630 and a male connector 640. The female connector 630 has a cylindrical cavity 631 formed into the mating surface 628. The cylindrical cavity 631 terminates in a floor 632. An annular groove 633 is formed into the floor 632. Optionally, the annular groove 633 may have an outer diameter equal to a diameter of the cylindrical cavity 631 or may have an outer diameter which is less than a diameter of the cylindrical cavity 631. A channel 624 extends from a passage 626 to the floor 632 of the cylindrical cavity 631 of the female connector 630. The passage 626 extends from the channel 624 to the fluid port 610.

The male connector 640 has a cylindrical protuberance 641 extending from the mating surface 628. The cylindrical protuberance 641 terminates in a distal end 642. An annular ring 643 extends from the distal end 642. Optionally, the annular ring 643 may have an outer diameter which is equal to a diameter of the cylindrical protuberance 641 or the outer diameter of the annular ring 643 may be less than a diameter of the cylindrical protuberance 641. In contrast with the substrate block 404, no channel extends from the floor 642 of the male connector 640.

The annular ring 643 also has an inner diameter which is greater than a diameter of the channel 624 such that the distal end 642 of the cylindrical protuberance 641 forms an end surface of the cylindrical protuberance 641 and the annular ring 643 protrudes from the end surface.

The male connector 640 is configured to couple to a female connector of another substrate block 304 and provide a fluid-tight connection between the male and female connectors. Similarly, the female connector 630 is configured to couple to a male connector of another substrate block 304 and provide a fluid-tight connection between the male and female connectors. The male connectors 640 are configured to interface with any of the female connectors of the substrate blocks 304 and vice versa. This may be achieved by a close fit or interference fit between the respective surfaces. For example, a seal may be achieved by the outer diameter of the annular ring 643 or the diameter of the cylindrical protuberance 641 being greater than the diameter of the cylindrical cavity 630 or the outer diameter of the annular groove 633. Similarly, the inner diameter of the annular ring 643 may be less than the inner diameter of the annular groove 633. In other configurations, the end surface of the annular ring 643 may be configured to form a seal with a bottom surface of the annular ring 643. In yet other configurations, the distal end 642 of the cylindrical protuberance 641 may form a seal with the floor 632 of the female connector 630. The fasteners 320 may be used to compress the substrate blocks 304 and ensure that the male and female connectors remain mated. Other mating geometries are contemplated, with the goal of any connector geometry being to provide a fluid-tight connection between substrate blocks 304 within the substrate assembly 300. As can be seen, the end right configuration of the substrate block 604 has a single flow path extending from the fluid port 610 to the female connector 630. The flow path extends from the fluid port 610 via the passage 626 and the channel 624 to the female connector 630. The male connector 640 is fluidly isolated from the fluid port 610.

Two fastener cavities 650 are provided in the end surface 627. The fastener cavities 650 may be formed as stepped counter bores which are configured to receive both the nuts 322 and covers 323 or to receive the head of a bolt and a cover 323. The fastener cavities 650 are configured to ensure that both the nuts 322 and the cover 323 are recessed with respect to the end surface 627. No analogous fastener cavities 650 are formed in the mating surface 628 because the mating surface 628 is configured to allow mating of the substrate block 604 with another substrate block 304 while the end surface 627 forms an end surface of the substrate assembly 300.

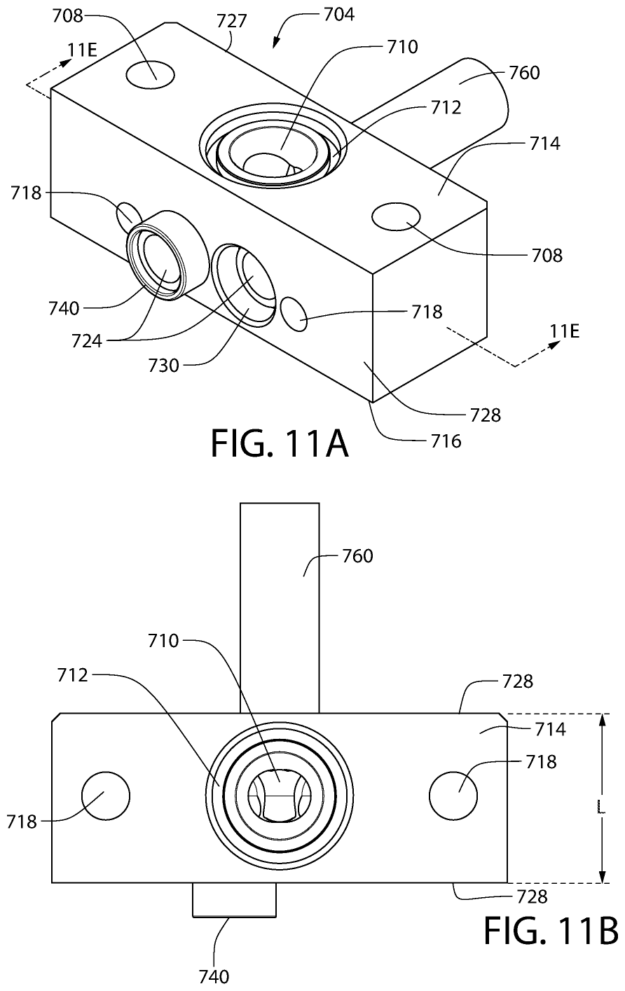

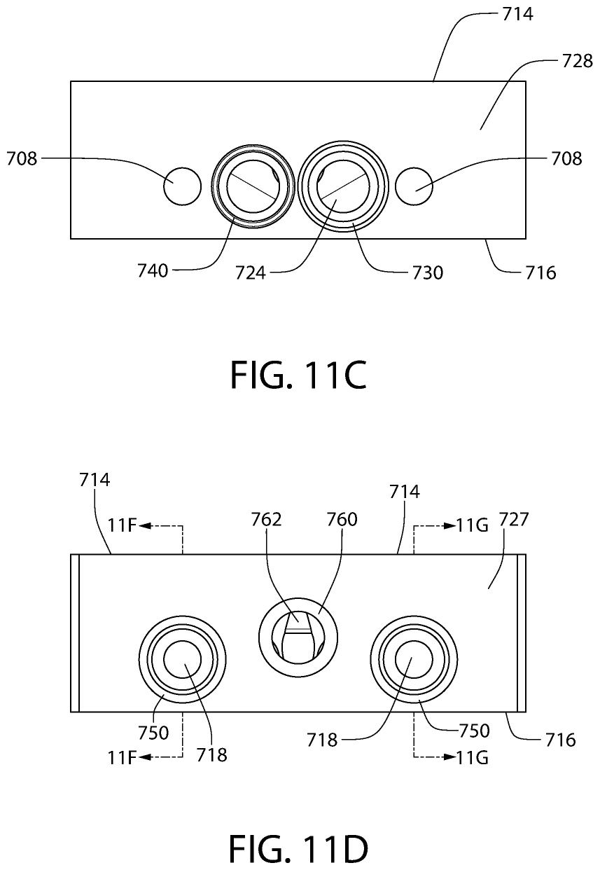

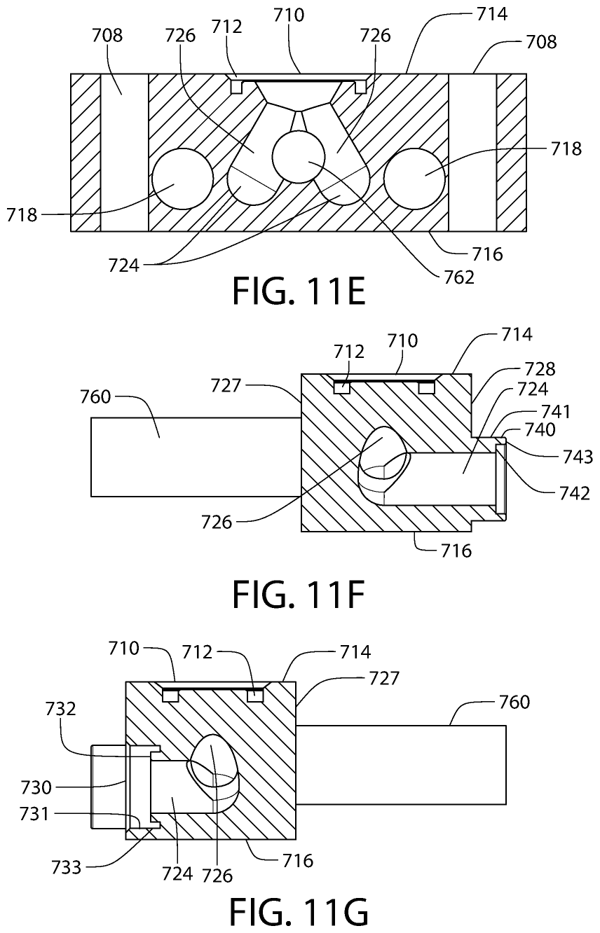

Turning to FIGS. 11A-G, a substrate block 704 is illustrated. The substrate block 704 has an end tee inlet configuration and may be utilized in the substrate assembly 300 described above. The substrate block 704 may be utilized as an end substrate block in the substrate assembly 300 as will be discussed in greater detail below. The substrate block 704 has a fluid port 710, the fluid port 710 having a seal cavity 712. The fluid port 712 is formed into a seal side mounting surface 714. Fastener passageways 708 are also formed into the seal side mounting surface 714 and extend through the substrate block 704. A bottom surface 716 is opposite the seal side mounting surface 714.

The substrate block 704 also has an end surface 727 and an opposite mating surface 728. The substrate block 704 has a length L measured from the end surface 727 to the mating surface 728. A tube portion 760 is formed into the end surface 727, the tube portion 760 extending from the end surface 727. The tube portion 760 is in fluid communication with the fluid port 710. The tube portion 760 may be used to enable coupling of an inlet or outlet, a separate component, or any other required connection. The tube portion 760 may be welded to another tube to enable a fluid tight connection. Alternately, a coupling or connector may be used to provide a connection to the tube portion 760. The tube portion 760 incorporates a channel 762 which allows fluid flow therethrough, the channel 762 in fluid communication with the fluid port 710.

Coupling holes 718 extend from the end surface 727 to the mating surface 728 to allow passage of the fasteners 320 as described above. The mating surface 728 also has a female connector 730 and a male connector 740. The female connector 730 has a cylindrical cavity 731 formed into the mating surface 728. The cylindrical cavity 731 terminates in a floor 732. An annular groove 733 is formed into the floor 732. Optionally, the annular groove 733 may have an outer diameter equal to a diameter of the cylindrical cavity 731 or may have an outer diameter which is less than a diameter of the cylindrical cavity 731. A channel 724 extends from a passage 726 to the floor 732 of the cylindrical cavity 731 of the female connector 730. The passage 726 extends from the channel 724 to the fluid port 710.

The male connector 740 has a cylindrical protuberance 741 extending from the mating surface 728. The cylindrical protuberance 741 terminates in a distal end 742. An annular ring 743 extends from the distal end 742. Optionally, the annular ring 743 may have an outer diameter which is equal to a diameter of the cylindrical protuberance 741 or the outer diameter of the annular ring 743 may be less than a diameter of the cylindrical protuberance 741. A channel 724 extends from the distal end 742 of the cylindrical protuberance 741 of the male connector 740 to a passage 726. The passage 726 extends from the channel 724 to the fluid port. The annular ring 743 also has an inner diameter which is greater than a diameter of the channel 724 such that the distal end 742 of the cylindrical protuberance 741 forms an end surface of the cylindrical protuberance 741 and the annular ring 743 protrudes from the end surface.

The male connector 740 is configured to couple to a female connector of another substrate block 304 and provide a fluid-tight connection between the male and female connectors. Similarly, the female connector 730 is configured to couple to a male connector of another substrate block 304 and provide a fluid-tight connection between the male and female connectors. The male connectors 740 are configured to interface with any of the female connectors of the substrate blocks 304 and vice versa. This may be achieved by a close fit or interference fit between the respective surfaces. For example, a seal may be achieved by the outer diameter of the annular ring 743 or the diameter of the cylindrical protuberance 741 being greater than the diameter of the cylindrical cavity 730 or the outer diameter of the annular groove 733. Similarly, the inner diameter of the annular ring 743 may be less than the inner diameter of the annular groove 733. In other configurations, the end surface of the annular ring 743 may be configured to form a seal with a bottom surface of the annular ring 743. In yet other configurations, the distal end 742 of the cylindrical protuberance 741 may form a seal with the floor 732 of the female connector 730. The fasteners 320 may be used to compress the substrate blocks 304 and ensure that the male and female connectors remain mated. Other mating geometries are contemplated, with the goal of any connector geometry being to provide a fluid-tight connection between substrate blocks 304 within the substrate assembly 300. As can be seen, the end tee configuration of the substrate block 704 has a flow path extending from the fluid port 710 to the female connector 730 and the male connector 740. The flow path extends from the fluid port 710 via the passage 726 and the channel 724 to the female connector 730. The flow path also extends from the fluid port 710 via the other passage 726 to the other channel 724, and then to the male connector 740.

Two fastener cavities 750 are provided in the end surface 727. The fastener cavities 750 may be formed as stepped counter bores which are configured to receive both the nuts 322 and covers 323 or to receive the head of a bolt and a cover 323. The fastener cavities 750 are configured to ensure that both the nuts 322 and the cover 323 are recessed with respect to the end surface 727. No analogous fastener cavities 750 are formed in the mating surface 728 because the mating surface 728 is configured to allow mating of the substrate block 704 with another substrate block 304 while the end surface 727 forms an end surface of the substrate assembly 300.

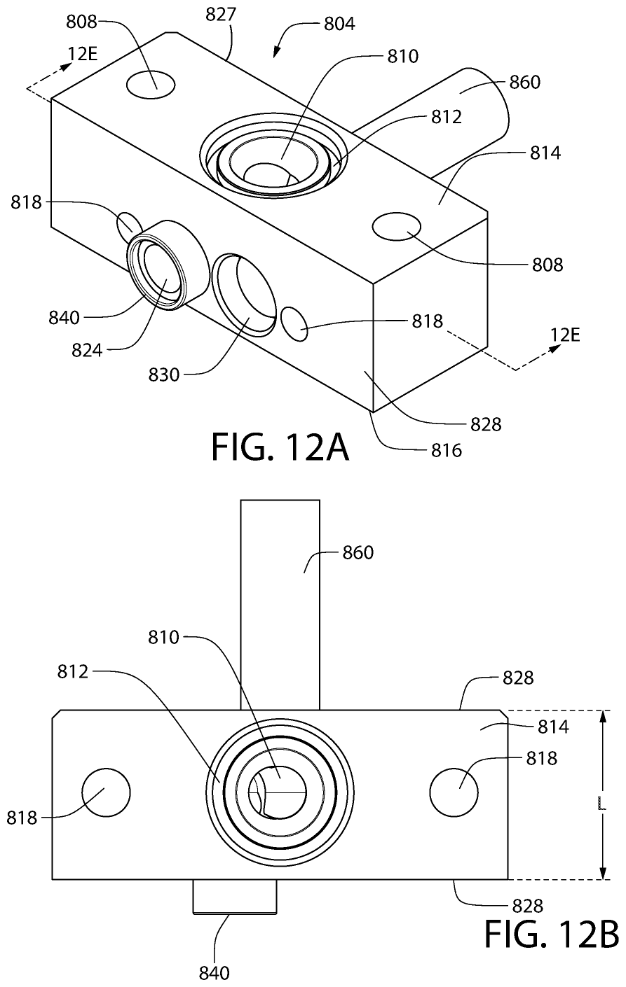

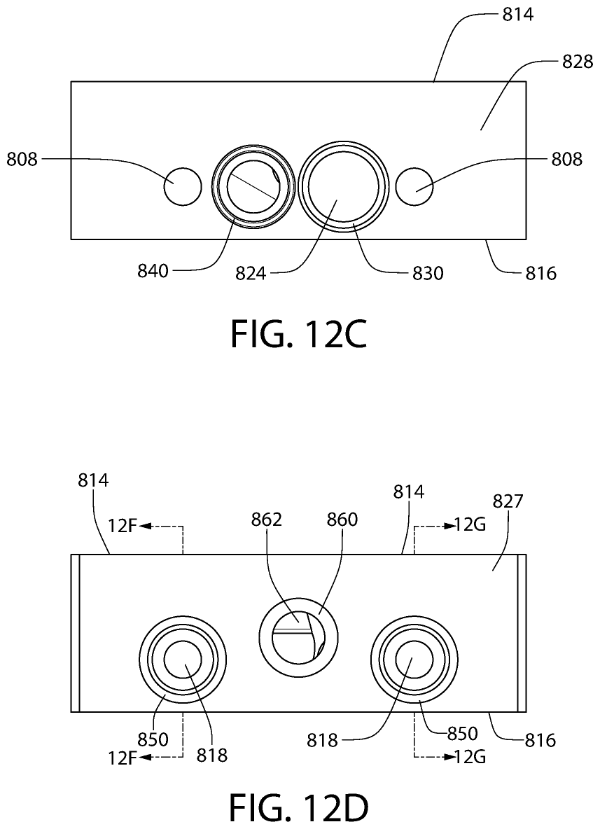

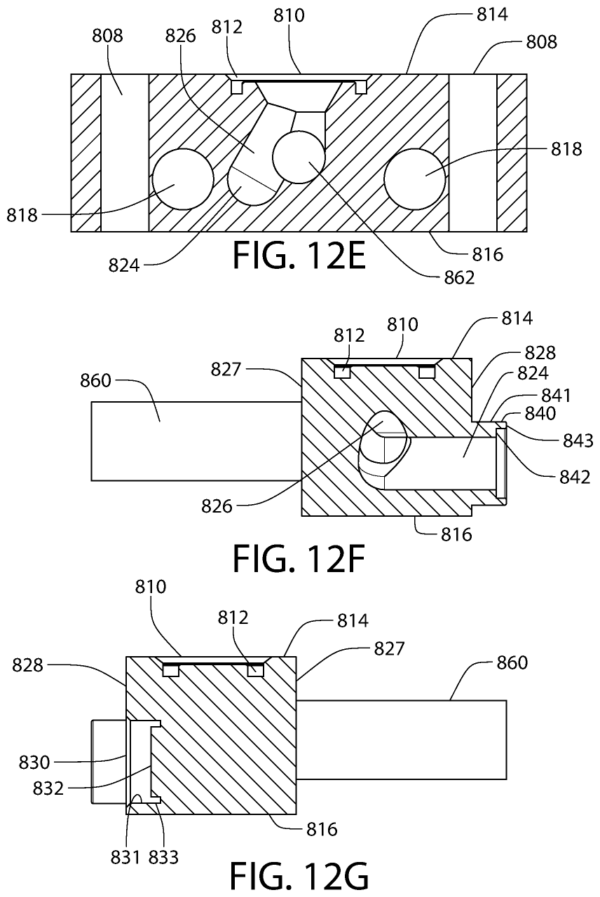

Turning to FIGS. 12A-G, a substrate block 804 is illustrated. The substrate block 804 has an end left inlet configuration and may be utilized in the substrate assembly 300 described above. The substrate block 804 may be utilized as an end substrate block in the substrate assembly 300 as will be discussed in greater detail below. The substrate block 804 has a fluid port 810, the fluid port 810 having a seal cavity 812. The fluid port 812 is formed into a seal side mounting surface 814. Fastener passageways 808 are also formed into the seal side mounting surface 814 and extend through the substrate block 804. A bottom surface 816 is opposite the seal side mounting surface 814.

The substrate block 804 also has an end surface 827 and an opposite mating surface 828. The substrate block 804 has a length L measured from the end surface 827 to the mating surface 828. A tube portion 860 is formed into the end surface 827, the tube portion 860 extending from the end surface 827. The tube portion 860 is in fluid communication with the fluid port 810. The tube portion 860 may be used to enable coupling of an inlet or outlet, a separate component, or any other required connection. The tube portion 860 may be welded to another tube to enable a fluid tight connection. Alternately, a coupling or connector may be used to provide a connection to the tube portion 860. The tube portion 860 incorporates a channel 862 which allows fluid flow therethrough, the channel 862 in fluid communication with the fluid port 810.

Coupling holes 818 extend from the end surface 827 to the mating surface 828 to allow passage of the fasteners 320 as described above. The mating surface 828 also has a female connector 830 and a male connector 840. The female connector 830 has a cylindrical cavity 831 formed into the mating surface 828. The cylindrical cavity 831 terminates in a floor 832. An annular groove 833 is formed into the floor 832. Optionally, the annular groove 833 may have an outer diameter equal to a diameter of the cylindrical cavity 831 or may have an outer diameter which is less than a diameter of the cylindrical cavity 831. No channel extends from the floor 832 of the cylindrical cavity 831 of the female connector 830. Thus, there is no flow path from the fluid port 810 to the female connector 830.

The male connector 840 has a cylindrical protuberance 841 extending from the mating surface 828. The cylindrical protuberance 841 terminates in a distal end 842. An annular ring 843 extends from the distal end 842. Optionally, the annular ring 843 may have an outer diameter which is equal to a diameter of the cylindrical protuberance 841 or the outer diameter of the annular ring 843 may be less than a diameter of the cylindrical protuberance 841. A channel 824 extends from the distal end 842 of the cylindrical protuberance 841 of the male connector 840 to a passage 826. The passage 826 extends from the channel 824 to the fluid port. The annular ring 843 also has an inner diameter which is greater than a diameter of the channel 824 such that the distal end 842 of the cylindrical protuberance 841 forms an end surface of the cylindrical protuberance 841 and the annular ring 843 protrudes from the end surface.

The male connector 840 is configured to couple to a female connector of another substrate block 304 and provide a fluid-tight connection between the male and female connectors. Similarly, the female connector 830 is configured to couple to a male connector of another substrate block 304 and provide a fluid-tight connection between the male and female connectors. The male connectors 840 are configured to interface with any of the female connectors of the substrate blocks 304 and vice versa. This may be achieved by a close fit or interference fit between the respective surfaces. For example, a seal may be achieved by the outer diameter of the annular ring 843 or the diameter of the cylindrical protuberance 841 being greater than the diameter of the cylindrical cavity 830 or the outer diameter of the annular groove 833. Similarly, the inner diameter of the annular ring 843 may be less than the inner diameter of the annular groove 833. In other configurations, the end surface of the annular ring 843 may be configured to form a seal with a bottom surface of the annular ring 843. In yet other configurations, the distal end 842 of the cylindrical protuberance 841 may form a seal with the floor 832 of the female connector 830. The fasteners 320 may be used to compress the substrate blocks 304 and ensure that the male and female connectors remain mated. Other mating geometries are contemplated, with the goal of any connector geometry being to provide a fluid-tight connection between substrate blocks 304 within the substrate assembly 300. As can be seen, the end left inlet configuration of the substrate block 804 has a single flow path extending from the fluid port 810 to the male connector 840. The flow path extends from the fluid port 810 via the passage 826 and the channel 824 to the male connector 840. The female connector 830 is fluidly isolated from the fluid port 810.

Two fastener cavities 850 are provided in the end surface 827. The fastener cavities 850 may be formed as stepped counter bores which are configured to receive both the nuts 322 and covers 323 or to receive the head of a bolt and a cover 323. The fastener cavities 850 are configured to ensure that both the nuts 322 and the cover 323 are recessed with respect to the end surface 827. No analogous fastener cavities 850 are formed in the mating surface 828 because the mating surface 828 is configured to allow mating of the substrate block 804 with another substrate block 304 while the end surface 827 forms an end surface of the substrate assembly 300.

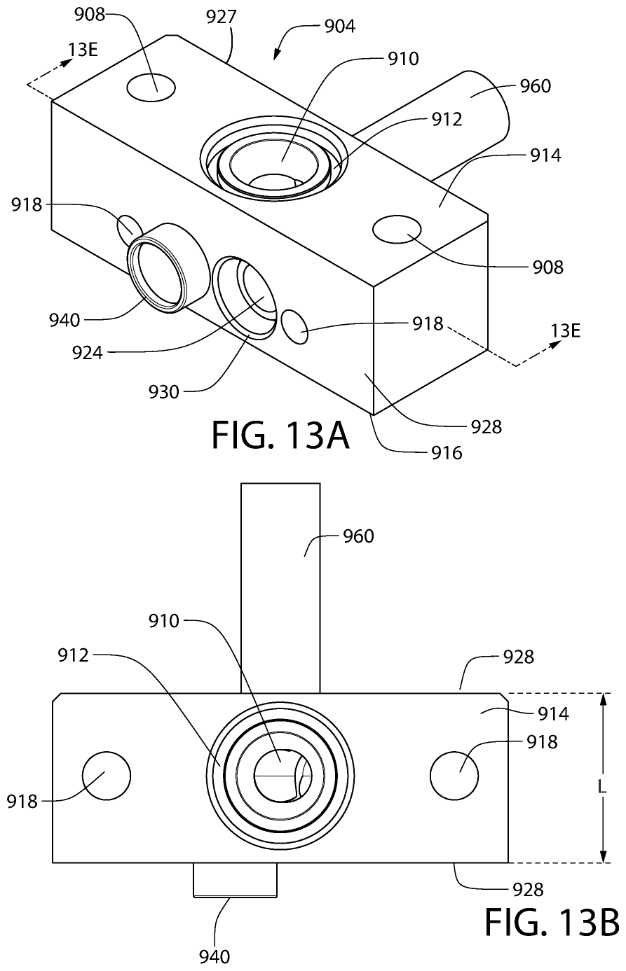

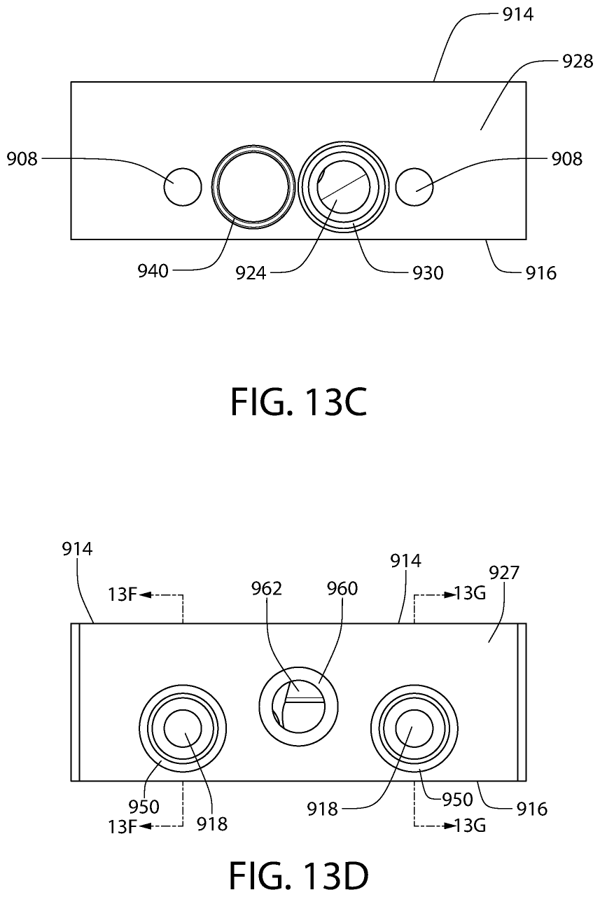

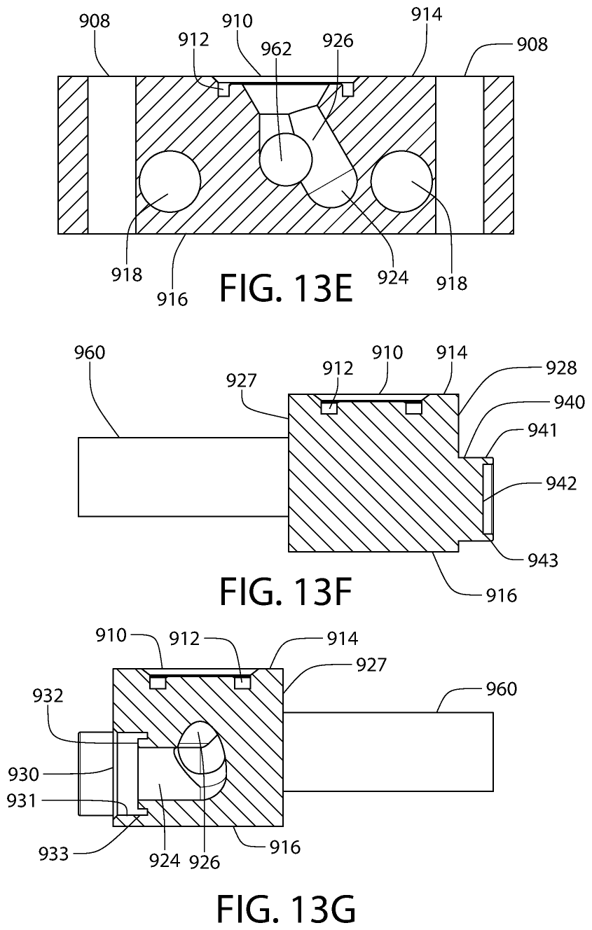

Turning to FIGS. 13A-G, a substrate block 904 is illustrated. The substrate block 904 has an end right inlet configuration and may be utilized in the substrate assembly 300 described above. The substrate block 904 may be utilized as an end substrate block in the substrate assembly 300 as will be discussed in greater detail below. The substrate block 904 has a fluid port 910, the fluid port 910 having a seal cavity 912. The fluid port 912 is formed into a seal side mounting surface 914. Fastener passageways 908 are also formed into the seal side mounting surface 914 and extend through the substrate block 904. A bottom surface 916 is opposite the seal side mounting surface 914.

The substrate block 904 also has an end surface 927 and an opposite mating surface 928. The substrate block 904 has a length L measured from the end surface 927 to the mating surface 928. A tube portion 960 is formed into the end surface 927, the tube portion 960 extending from the end surface 927. The tube portion 960 is in fluid communication with the fluid port 910. The tube portion 960 may be used to enable coupling of an inlet or outlet, a separate component, or any other required connection. The tube portion 960 may be welded to another tube to enable a fluid tight connection. Alternately, a coupling or connector may be used to provide a connection to the tube portion 960. The tube portion 960 incorporates a channel 962 which allows fluid flow therethrough, the channel 962 in fluid communication with the fluid port 910.

Coupling holes 918 extend from the end surface 927 to the mating surface 928 to allow passage of the fasteners 320 as described above. The mating surface 928 also has a female connector 930 and a male connector 940. The female connector 930 has a cylindrical cavity 931 formed into the mating surface 928. The cylindrical cavity 931 terminates in a floor 932. An annular groove 933 is formed into the floor 932. Optionally, the annular groove 933 may have an outer diameter equal to a diameter of the cylindrical cavity 931 or may have an outer diameter which is less than a diameter of the cylindrical cavity 931. A channel 924 extends from a passage 926 to the floor 932 of the cylindrical cavity 931 of the female connector 930. The passage 926 extends from the channel 924 to the fluid port 910.

The male connector 940 has a cylindrical protuberance 941 extending from the mating surface 928. The cylindrical protuberance 941 terminates in a distal end 942. An annular ring 943 extends from the distal end 942. Optionally, the annular ring 943 may have an outer diameter which is equal to a diameter of the cylindrical protuberance 941 or the outer diameter of the annular ring 943 may be less than a diameter of the cylindrical protuberance 941. A channel 924 extends from the distal end 942 of the cylindrical protuberance 941 of the male connector 940 to a passage 926. The passage 926 extends from the channel 924 to the fluid port. The annular ring 943 also has an inner diameter which is greater than a diameter of the channel 924 such that the distal end 942 of the cylindrical protuberance 941 forms an end surface of the cylindrical protuberance 941 and the annular ring 943 protrudes from the end surface.

The male connector 940 is configured to couple to a female connector of another substrate block 304 and provide a fluid-tight connection between the male and female connectors. Similarly, the female connector 930 is configured to couple to a male connector of another substrate block 304 and provide a fluid-tight connection between the male and female connectors. The male connectors 940 are configured to interface with any of the female connectors of the substrate blocks 304 and vice versa. This may be achieved by a close fit or interference fit between the respective surfaces. For example, a seal may be achieved by the outer diameter of the annular ring 943 or the diameter of the cylindrical protuberance 941 being greater than the diameter of the cylindrical cavity 930 or the outer diameter of the annular groove 933. Similarly, the inner diameter of the annular ring 943 may be less than the inner diameter of the annular groove 933. In other configurations, the end surface of the annular ring 943 may be configured to form a seal with a bottom surface of the annular ring 943. In yet other configurations, the distal end 942 of the cylindrical protuberance 941 may form a seal with the floor 932 of the female connector 930. The fasteners 320 may be used to compress the substrate blocks 304 and ensure that the male and female connectors remain mated. Other mating geometries are contemplated, with the goal of any connector geometry being to provide a fluid-tight connection between substrate blocks 304 within the substrate assembly 300. As can be seen, the end right inlet configuration of the substrate block 904 has a single flow path extending from the fluid port 910 to the female connector 930. The flow path extends from the fluid port 910 via the passage 926 and the channel 924 to the female connector 930. The male connector 940 is fluidly isolated from the fluid port 910.

Two fastener cavities 950 are provided in the end surface 927. The fastener cavities 950 may be formed as stepped counter bores which are configured to receive both the nuts 322 and covers 323 or to receive the head of a bolt and a cover 323. The fastener cavities 950 are configured to ensure that both the nuts 322 and the cover 323 are recessed with respect to the end surface 927. No analogous fastener cavities 950 are formed in the mating surface 928 because the mating surface 928 is configured to allow mating of the substrate block 904 with another substrate block 304 while the end surface 927 forms an end surface of the substrate assembly 300.

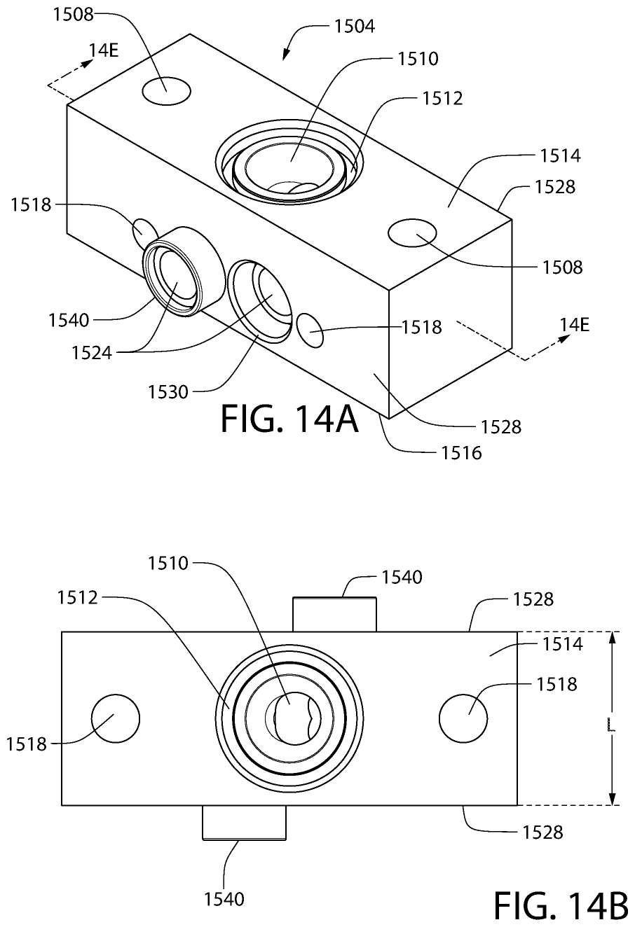

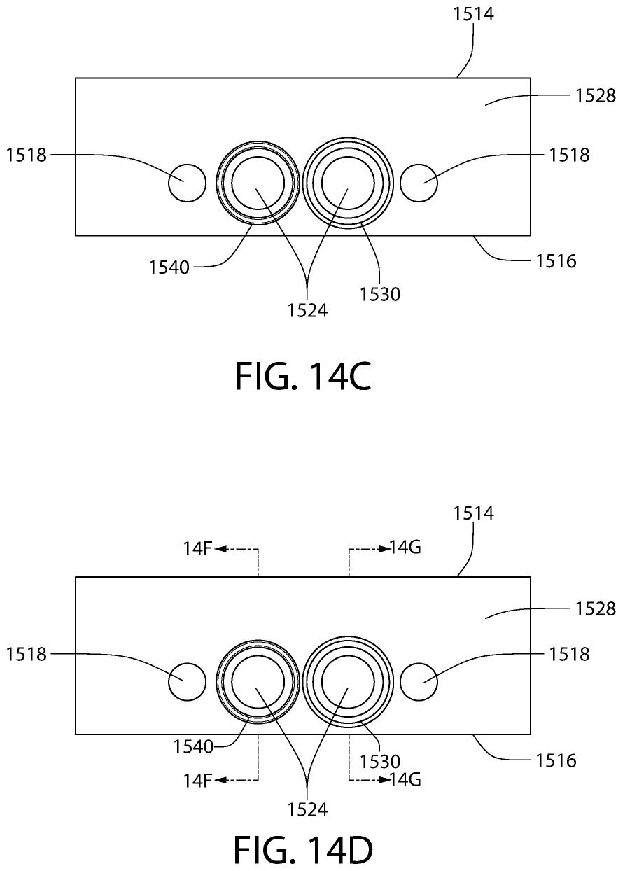

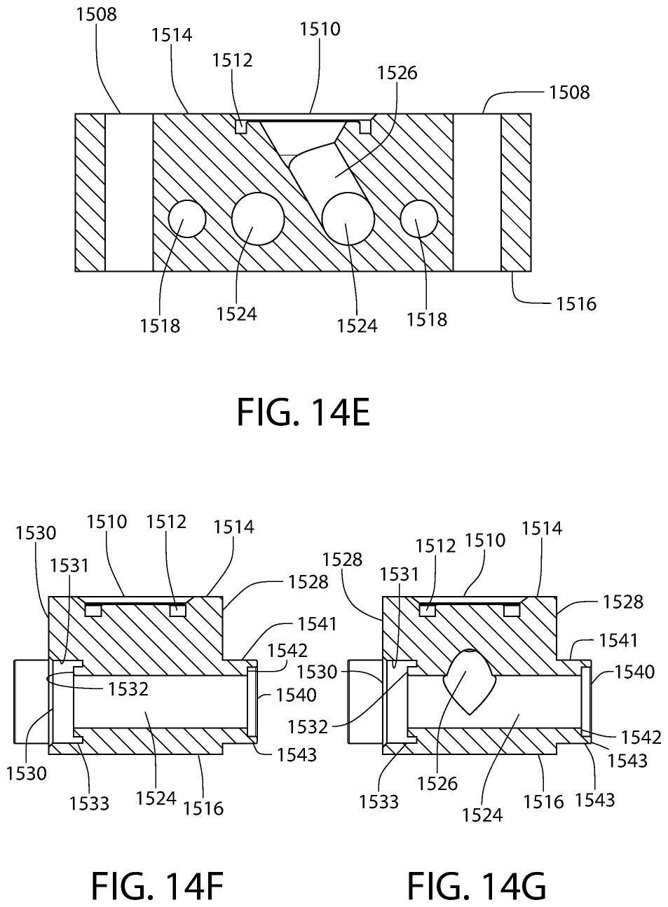

Turning to FIGS. 14A-G, a substrate block 1504 is illustrated. The substrate block 1504 has a connector tee through configuration and may be utilized in the substrate assembly 300 described above. The substrate block 1504 may be utilized as a connector substrate block in the substrate assembly 300 as will be discussed in greater detail below. Otherwise stated, the substrate block 1504 may be a substrate block 304 which is located between two end substrate blocks 304. The connector substrate blocks allow coupling of additional components 200 as well as routing of flow from the channels in each of the substrate blocks 304 to enable flexible configuration of the flow path. The substrate block 1504 has a fluid port 1510, the fluid port 1510 having a seal cavity 1512. The fluid port 1512 is formed into a seal side mounting surface 1514. Fastener passageways 1508 are also formed into the seal side mounting surface 1514 and extend through the substrate block 1504. A bottom surface 1516 is opposite the seal side mounting surface 1514.

The substrate block 1504 also has opposing mating surfaces 1528. The substrate block 1504 has a length L measured from the first mating surface 1528 to the second mating surface 1528. Coupling holes 1518 extend from one mating surface 1528 to the other mating surface 1528 to allow passage of the fasteners 320 as described above. The mating surfaces 1528 each have a female connector 1530 and a male connector 1540. The female connector 1530 has a cylindrical cavity 1531 formed into the mating surface 1528. The cylindrical cavity 1531 terminates in a floor 1532. An annular groove 1533 is formed into the floor 1532. Optionally, the annular groove 1533 may have an outer diameter equal to a diameter of the cylindrical cavity 1531 or may have an outer diameter which is less than a diameter of the cylindrical cavity 1531.

The male connectors 1540 each have a cylindrical protuberance 1541 extending from the mating surface 1528. The cylindrical protuberance 1541 terminates in a distal end 1542. An annular ring 1543 extends from the distal end 1542. Optionally, the annular ring 1543 may have an outer diameter which is equal to a diameter of the cylindrical protuberance 1541 or the outer diameter of the annular ring 1543 may be less than a diameter of the cylindrical protuberance 1541. The annular ring 1543 also has an inner diameter which is greater than a diameter of the channel 1524 such that the distal end 1542 of the cylindrical protuberance 1541 forms an end surface of the cylindrical protuberance 1541 and the annular ring 1543 protrudes from the end surface.

The male connectors 1540 are configured to couple to a female connector of another substrate block 304 and provide a fluid-tight connection between the male and female connectors. Similarly, the female connectors 1530 are configured to couple to a male connector of another substrate block 304 and provide a fluid-tight connection between the male and female connectors. The male connectors 1540 are configured to interface with any of the female connectors of the substrate blocks 304 and vice versa. This may be achieved by a close fit or interference fit between the respective surfaces. For example, a seal may be achieved by the outer diameter of the annular ring 1543 or the diameter of the cylindrical protuberance 1541 being greater than the diameter of the cylindrical cavity 1530 or the outer diameter of the annular groove 1533. Similarly, the inner diameter of the annular ring 1543 may be less than the inner diameter of the annular groove 1533. In other configurations, the end surface of the annular ring 1543 may be configured to form a seal with a bottom surface of the annular ring 1543. In yet other configurations, the distal end 1542 of the cylindrical protuberance 1541 may form a seal with the floor 1532 of the female connector 1530. The fasteners 320 may be used to compress the substrate blocks 304 and ensure that the male and female connectors remain mated. Other mating geometries are contemplated, with the goal of any connector geometry being to provide a fluid-tight connection between substrate blocks 304 within the substrate assembly 300.

As can be seen, the connector tee through configuration of the substrate block 1504 has a flow path extending from the fluid port 1510 to the female connector 1530 on the first mating surface 1528 and the male connector 1540 on the second mating surface 1528. A channel 1524 extends from the floor 1532 of the cylindrical cavity 1531 of the female connector 1530 on the first mating surface 1528 to the distal end 1542 of the cylindrical protuberance 1541 of the male connector 1540 on the second mating surface 1528. A passage 1526 extends from the channel 1524 to the fluid port 1510. Another flow path is formed by a second channel 1524 that extends from the distal end 1542 of the cylindrical protuberance 1541 of the male connector 1540 on the first mating surface 1528 to the floor 1532 of the cylindrical cavity 1531 of the female connector 1530 on the second mating surface 1528. The second channel 1524 is not coupled to the fluid port 1510. The second channel 1524 is isolated from the fluid port 1510.

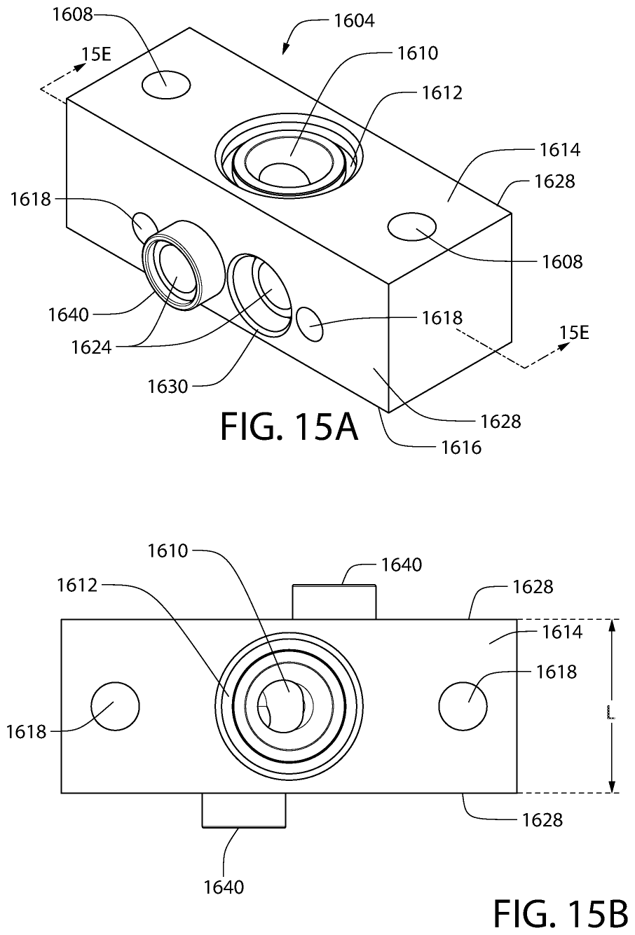

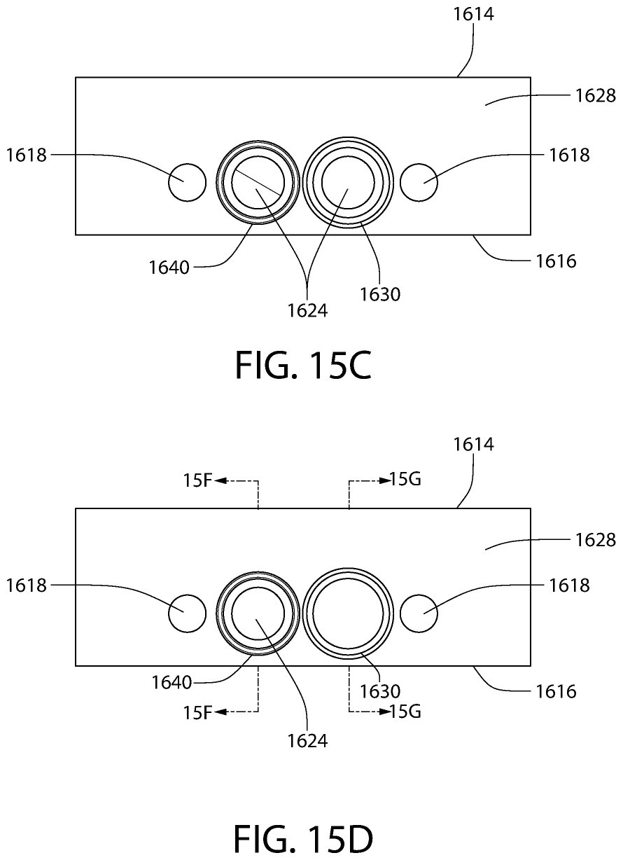

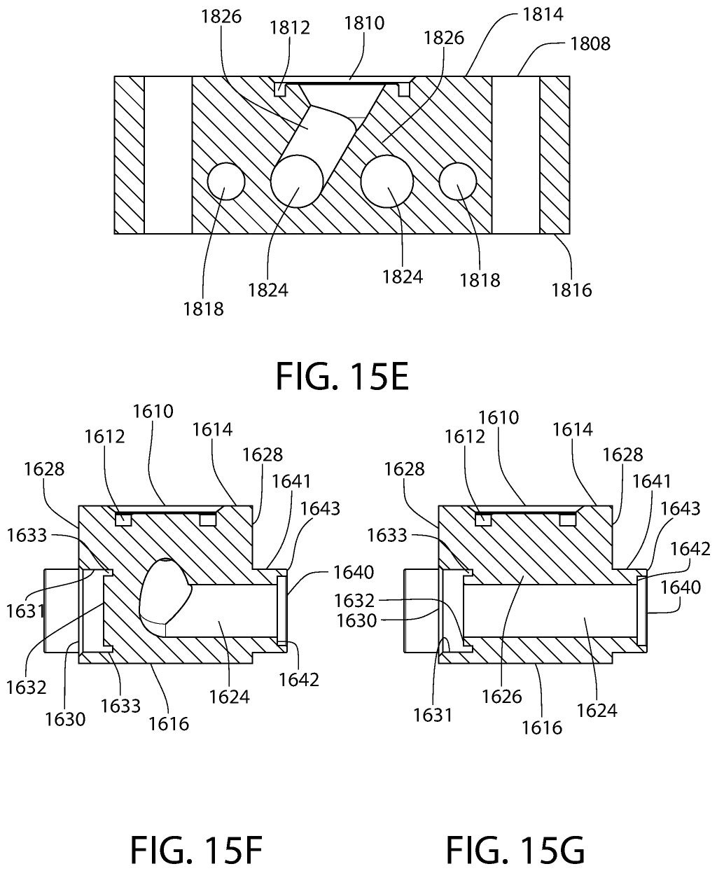

Turning to FIGS. 15A-G, a substrate block 1604 is illustrated. The substrate block 1604 has a connector left through configuration and may be utilized in the substrate assembly 300 described above. The substrate block 1604 may be utilized as a connector substrate block in the substrate assembly 300 as will be discussed in greater detail below. Otherwise stated, the substrate block 1604 may be a substrate block 304 which is located between two end substrate blocks 304. The connector substrate blocks allow coupling of additional components 200 as well as routing of flow from the channels in each of the substrate blocks 304 to enable flexible configuration of the flow path. The substrate block 1604 has a fluid port 1610, the fluid port 1610 having a seal cavity 1612. The fluid port 1612 is formed into a seal side mounting surface 1614. Fastener passageways 1608 are also formed into the seal side mounting surface 1614 and extend through the substrate block 1604. A bottom surface 1616 is opposite the seal side mounting surface 1614.

The substrate block 1604 also has opposing mating surfaces 1628. The substrate block 1604 has a length L measured from the first mating surface 1628 to the second mating surface 1628. Coupling holes 1618 extend from one mating surface 1628 to the other mating surface 1628 to allow passage of the fasteners 320 as described above. The mating surfaces 1628 each have a female connector 1630 and a male connector 1640. The female connector 1630 has a cylindrical cavity 1631 formed into the mating surface 1628. The cylindrical cavity 1631 terminates in a floor 1632. An annular groove 1633 is formed into the floor 1632. Optionally, the annular groove 1633 may have an outer diameter equal to a diameter of the cylindrical cavity 1631 or may have an outer diameter which is less than a diameter of the cylindrical cavity 1631.

The male connectors 1640 each have a cylindrical protuberance 1641 extending from the mating surface 1628. The cylindrical protuberance 1641 terminates in a distal end 1642. An annular ring 1643 extends from the distal end 1642. Optionally, the annular ring 1643 may have an outer diameter which is equal to a diameter of the cylindrical protuberance 1641 or the outer diameter of the annular ring 1643 may be less than a diameter of the cylindrical protuberance 1641. The annular ring 1643 also has an inner diameter which is greater than a diameter of the channel 1624 such that the distal end 1642 of the cylindrical protuberance 1641 forms an end surface of the cylindrical protuberance 1641 and the annular ring 1643 protrudes from the end surface.

The male connectors 1640 are configured to couple to a female connector of another substrate block 304 and provide a fluid-tight connection between the male and female connectors. Similarly, the female connectors 1630 are configured to couple to a male connector of another substrate block 304 and provide a fluid-tight connection between the male and female connectors. The male connectors 1640 are configured to interface with any of the female connectors of the substrate blocks 304 and vice versa. This may be achieved by a close fit or interference fit between the respective surfaces. For example, a seal may be achieved by the outer diameter of the annular ring 1643 or the diameter of the cylindrical protuberance 1641 being greater than the diameter of the cylindrical cavity 1630 or the outer diameter of the annular groove 1633. Similarly, the inner diameter of the annular ring 1643 may be less than the inner diameter of the annular groove 1633. In other configurations, the end surface of the annular ring 1643 may be configured to form a seal with a bottom surface of the annular ring 1643. In yet other configurations, the distal end 1642 of the cylindrical protuberance 1641 may form a seal with the floor 1632 of the female connector 1630. The fasteners 320 may be used to compress the substrate blocks 304 and ensure that the male and female connectors remain mated. Other mating geometries are contemplated, with the goal of any connector geometry being to provide a fluid-tight connection between substrate blocks 304 within the substrate assembly 300.

As can be seen, the connector left through configuration of the substrate block 1604 has a flow path extending from the fluid port 1610 to the male connector 1640 on the first mating surface 1628. A channel 1624 extends from the distal end 1642 of the cylindrical protuberance 1641 of the male connector 1640 on the first mating surface 1628 to a passage 1626. The passage 1626 extends from the channel 1624 to the fluid port 1610. Another flow path is formed by a second channel 1624 that extends from the floor 1632 of the cylindrical cavity 1631 of the female connector 1630 on the first mating surface 1628 to the distal end 1642 of the cylindrical protuberance 1641 of the male connector 1640 on the second mating surface 1628. The second channel 1624 is not coupled to the fluid port 1610. The second channel 1624 is isolated from the fluid port 1610.

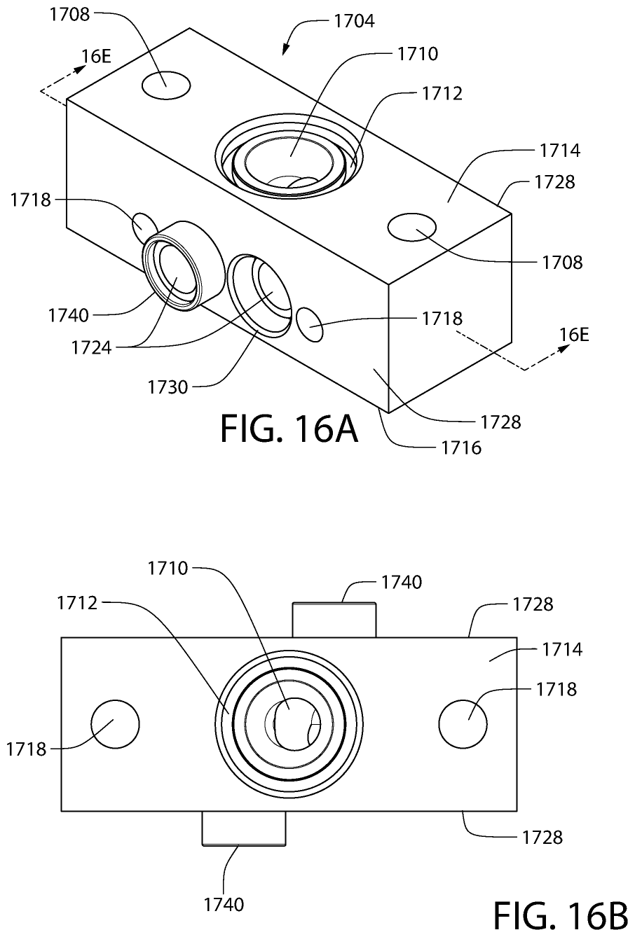

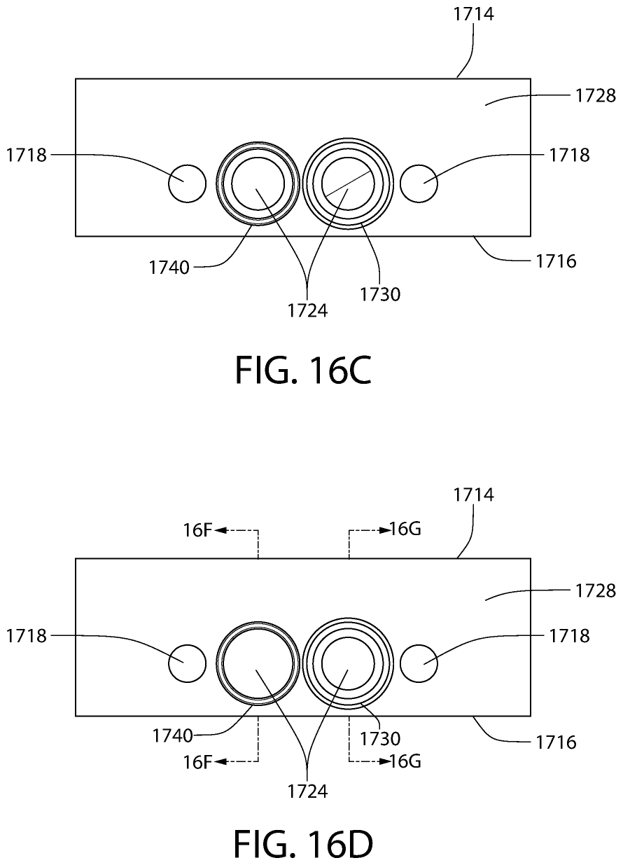

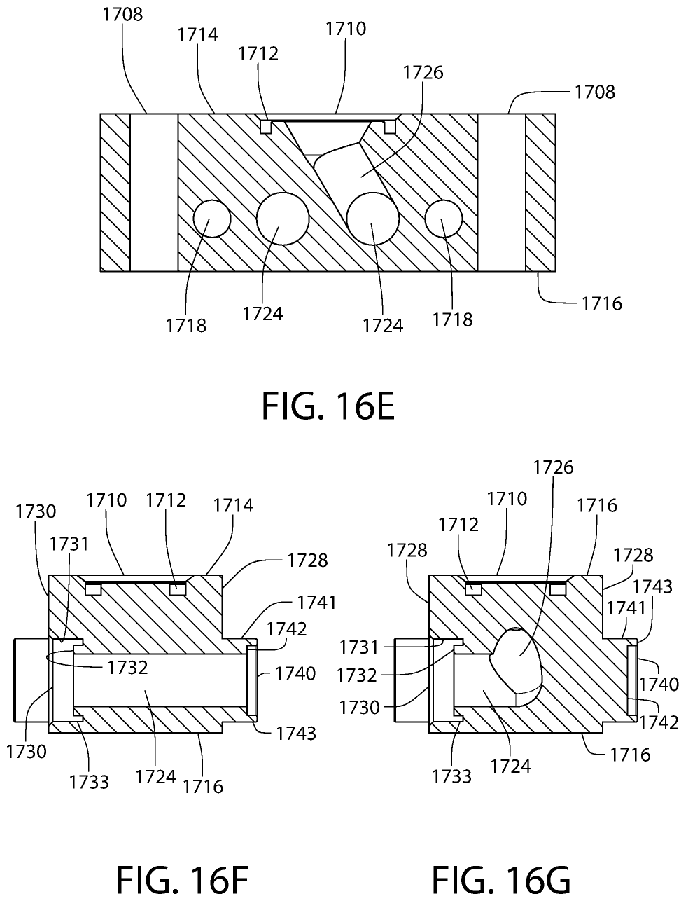

Turning to FIGS. 16A-G, a substrate block 1704 is illustrated. The substrate block 1704 has a connector right through configuration and may be utilized in the substrate assembly 300 described above. The substrate block 1704 may be utilized as a connector substrate block in the substrate assembly 300 as will be discussed in greater detail below. Otherwise stated, the substrate block 1704 may be a substrate block 304 which is located between two end substrate blocks 304. The connector substrate blocks allow coupling of additional components 200 as well as routing of flow from the channels in each of the substrate blocks 304 to enable flexible configuration of the flow path. The substrate block 1704 has a fluid port 1710, the fluid port 1710 having a seal cavity 1712. The fluid port 1712 is formed into a seal side mounting surface 1714. Fastener passageways 1708 are also formed into the seal side mounting surface 1714 and extend through the substrate block 1704. A bottom surface 1716 is opposite the seal side mounting surface 1714.

The substrate block 1704 also has opposing mating surfaces 1728. The substrate block 1704 has a length L measured from the first mating surface 1728 to the second mating surface 1728. Coupling holes 1718 extend from one mating surface 1728 to the other mating surface 1728 to allow passage of the fasteners 320 as described above. The mating surfaces 1728 each have a female connector 1730 and a male connector 1740. The female connector 1730 has a cylindrical cavity 1731 formed into the mating surface 1728. The cylindrical cavity 1731 terminates in a floor 1732. An annular groove 1733 is formed into the floor 1732. Optionally, the annular groove 1733 may have an outer diameter equal to a diameter of the cylindrical cavity 1731 or may have an outer diameter which is less than a diameter of the cylindrical cavity 1731.

The male connectors 1740 each have a cylindrical protuberance 1741 extending from the mating surface 1728. The cylindrical protuberance 1741 terminates in a distal end 1742. An annular ring 1743 extends from the distal end 1742. Optionally, the annular ring 1743 may have an outer diameter which is equal to a diameter of the cylindrical protuberance 1741 or the outer diameter of the annular ring 1743 may be less than a diameter of the cylindrical protuberance 1741. The annular ring 1743 also has an inner diameter which is greater than a diameter of the channel 1724 such that the distal end 1742 of the cylindrical protuberance 1741 forms an end surface of the cylindrical protuberance 1741 and the annular ring 1743 protrudes from the end surface.

The male connectors 1740 are configured to couple to a female connector of another substrate block 304 and provide a fluid-tight connection between the male and female connectors. Similarly, the female connectors 1730 are configured to couple to a male connector of another substrate block 304 and provide a fluid-tight connection between the male and female connectors. The male connectors 1740 are configured to interface with any of the female connectors of the substrate blocks 304 and vice versa. This may be achieved by a close fit or interference fit between the respective surfaces. For example, a seal may be achieved by the outer diameter of the annular ring 1743 or the diameter of the cylindrical protuberance 1741 being greater than the diameter of the cylindrical cavity 1730 or the outer diameter of the annular groove 1733. Similarly, the inner diameter of the annular ring 1743 may be less than the inner diameter of the annular groove 1733. In other configurations, the end surface of the annular ring 1743 may be configured to form a seal with a bottom surface of the annular ring 1743. In yet other configurations, the distal end 1742 of the cylindrical protuberance 1741 may form a seal with the floor 1732 of the female connector 1730. The fasteners 320 may be used to compress the substrate blocks 304 and ensure that the male and female connectors remain mated. Other mating geometries are contemplated, with the goal of any connector geometry being to provide a fluid-tight connection between substrate blocks 304 within the substrate assembly 300.

As can be seen, the connector right through configuration of the substrate block 1704 has a flow path extending from the fluid port 1710 to the floor 1732 of the cylindrical cavity 1731 of the female connector 1730 on the first mating surface 1728. A channel 1724 extends from the floor 1732 of the cylindrical cavity 1731 of the female connector 1730 on the first mating surface 1728 to a passage 1726. The passage 1726 extends from the channel 1724 to the fluid port 1710. Another flow path is formed by a second channel 1724 that extends from the distal end 1742 of the cylindrical protuberance 1741 of the male connector 1740 on the first mating surface 1728 to the floor 1732 of the cylindrical cavity 1731 of the female connector 1730 on the second mating surface 1728. The second channel 1724 is not coupled to the fluid port 1710. The second channel 1724 is isolated from the fluid port 1710.

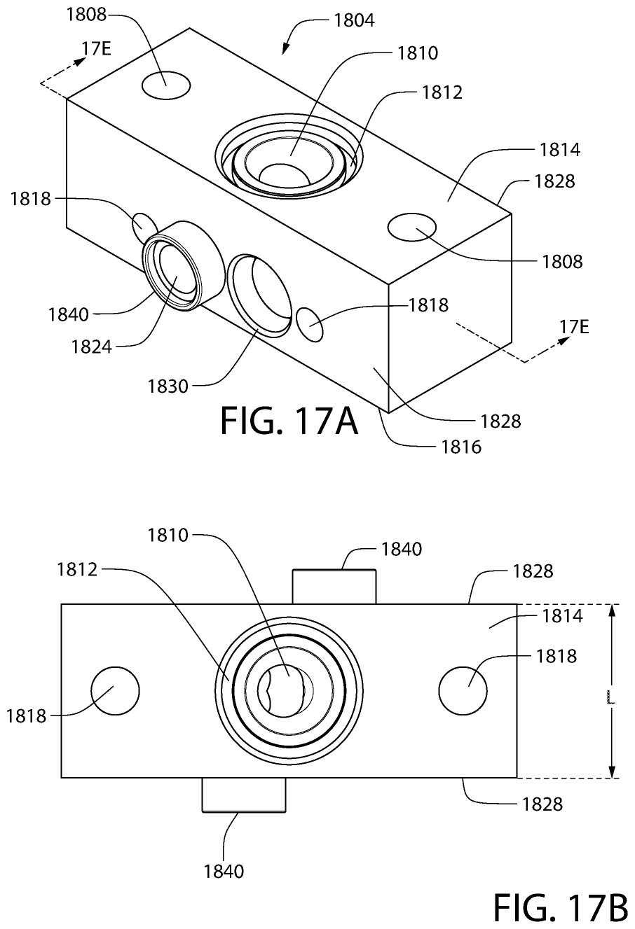

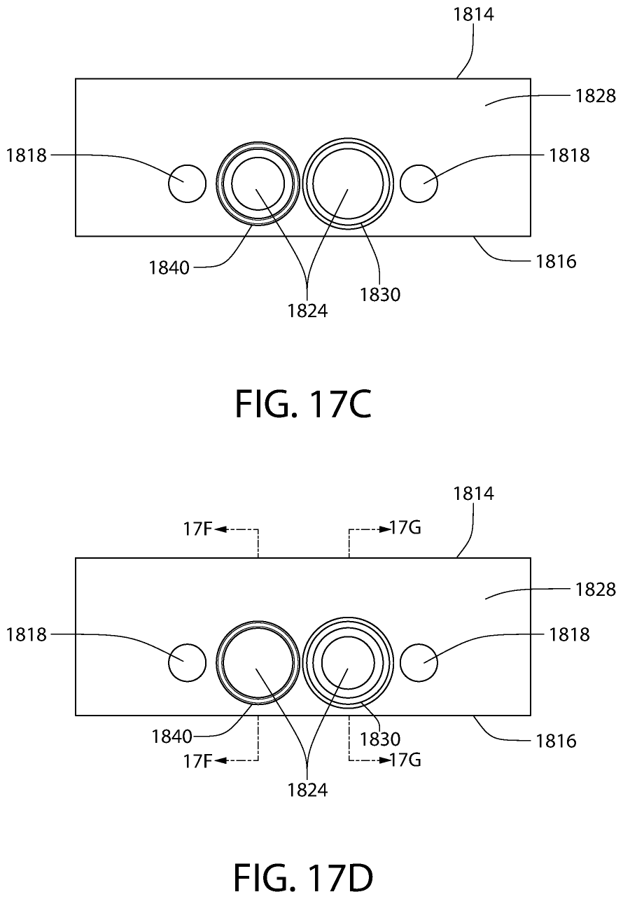

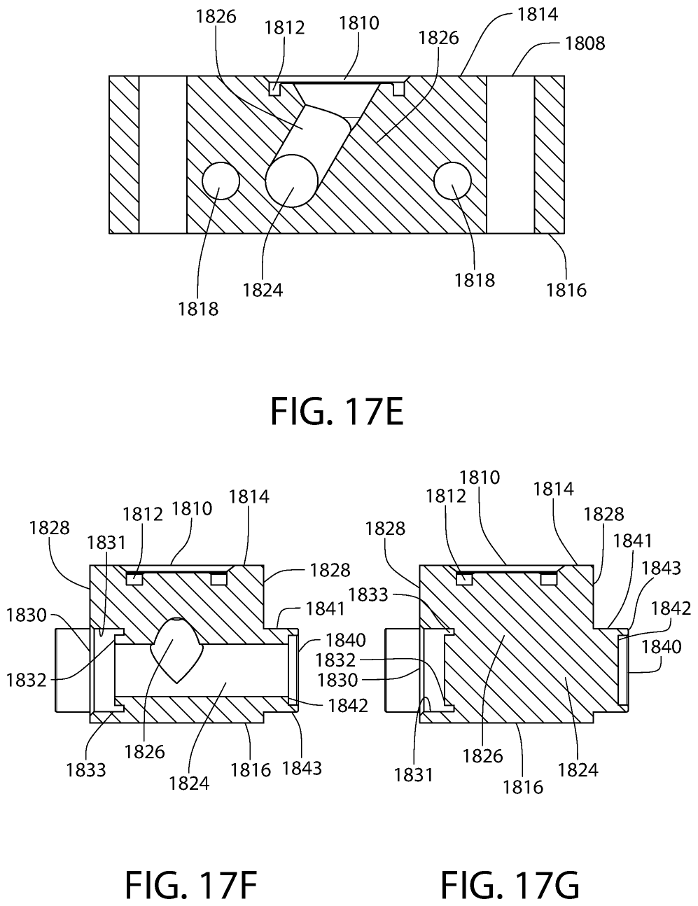

Turning to FIGS. 17A-G, a substrate block 1804 is illustrated. The substrate block 1804 has a connector tee blocking configuration and may be utilized in the substrate assembly 300 described above. The substrate block 1804 may be utilized as a connector substrate block in the substrate assembly 300 as will be discussed in greater detail below. Otherwise stated, the substrate block 1804 may be a substrate block 304 which is located between two end substrate blocks 304. The connector substrate blocks allow coupling of additional components 200 as well as routing of flow from the channels in each of the substrate blocks 304 to enable flexible configuration of the flow path. The substrate block 1804 has a fluid port 1810, the fluid port 1810 having a seal cavity 1812. The fluid port 1812 is formed into a seal side mounting surface 1814. Fastener passageways 1808 are also formed into the seal side mounting surface 1814 and extend through the substrate block 1804. A bottom surface 1816 is opposite the seal side mounting surface 1814.

The substrate block 1804 also has opposing mating surfaces 1828. The substrate block 1804 has a length L measured from the first mating surface 1828 to the second mating surface 1828. Coupling holes 1818 extend from one mating surface 1828 to the other mating surface 1828 to allow passage of the fasteners 320 as described above. The mating surfaces 1828 each have a female connector 1830 and a male connector 1840. The female connector 1830 has a cylindrical cavity 1831 formed into the mating surface 1828. The cylindrical cavity 1831 terminates in a floor 1832. An annular groove 1833 is formed into the floor 1832. Optionally, the annular groove 1833 may have an outer diameter equal to a diameter of the cylindrical cavity 1831 or may have an outer diameter which is less than a diameter of the cylindrical cavity 1831.

The male connectors 1840 each have a cylindrical protuberance 1841 extending from the mating surface 1828. The cylindrical protuberance 1841 terminates in a distal end 1842. An annular ring 1843 extends from the distal end 1842. Optionally, the annular ring 1843 may have an outer diameter which is equal to a diameter of the cylindrical protuberance 1841 or the outer diameter of the annular ring 1843 may be less than a diameter of the cylindrical protuberance 1841. The annular ring 1843 also has an inner diameter which is greater than a diameter of the channel 1824 such that the distal end 1842 of the cylindrical protuberance 1841 forms an end surface of the cylindrical protuberance 1841 and the annular ring 1843 protrudes from the end surface.

The male connectors 1840 are configured to couple to a female connector of another substrate block 304 and provide a fluid-tight connection between the male and female connectors. Similarly, the female connectors 1830 are configured to couple to a male connector of another substrate block 304 and provide a fluid-tight connection between the male and female connectors. The male connectors 1840 are configured to interface with any of the female connectors of the substrate blocks 304 and vice versa. This may be achieved by a close fit or interference fit between the respective surfaces. For example, a seal may be achieved by the outer diameter of the annular ring 1843 or the diameter of the cylindrical protuberance 1841 being greater than the diameter of the cylindrical cavity 1830 or the outer diameter of the annular groove 1833. Similarly, the inner diameter of the annular ring 1843 may be less than the inner diameter of the annular groove 1833. In other configurations, the end surface of the annular ring 1843 may be configured to form a seal with a bottom surface of the annular ring 1843. In yet other configurations, the distal end 1842 of the cylindrical protuberance 1841 may form a seal with the floor 1832 of the female connector 1830. The fasteners 320 may be used to compress the substrate blocks 304 and ensure that the male and female connectors remain mated. Other mating geometries are contemplated, with the goal of any connector geometry being to provide a fluid-tight connection between substrate blocks 304 within the substrate assembly 300.

As can be seen, the connector tee blocking configuration of the substrate block 1804 has a flow path extending from the fluid port 1810 to the male connector 1840 on the first mating surface 1828 and the female connector 1830 on the second mating surface 1828. A channel 1824 extends from the floor 1832 of the cylindrical cavity 1831 of the female connector 1830 on the second mating surface 1828 to the distal end 1842 of the cylindrical protuberance 1841 of the male connector 1840 on the first mating surface 1828. A passage 1826 extends from the channel 1824 to the fluid port 1810. No flow path is formed between the female connector 1830 on the first mating surface 1828 and the male connector 1840 on the second mating surface 1828.

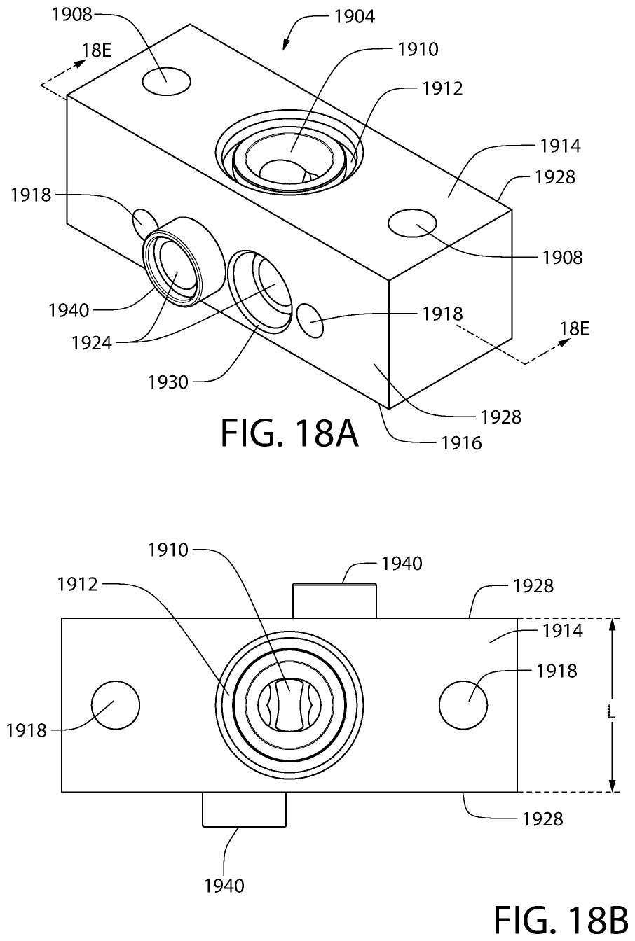

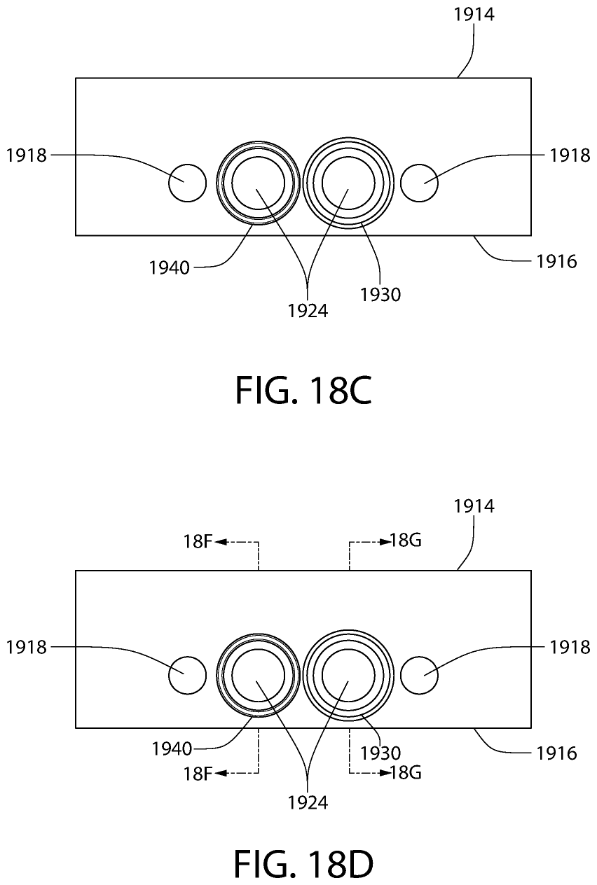

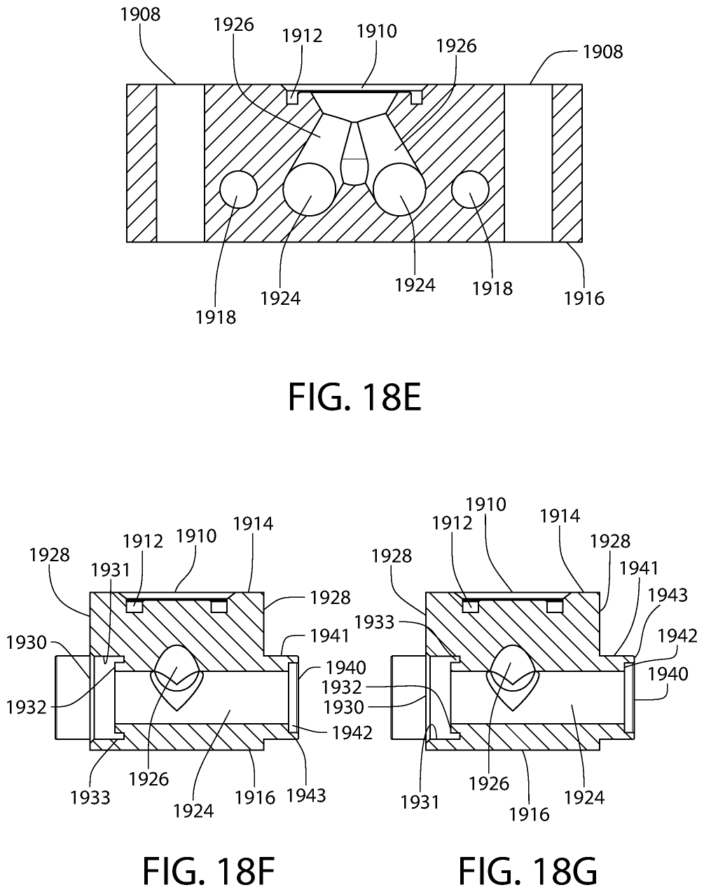

Turning to FIGS. 18A-G, a substrate block 1904 is illustrated. The substrate block 1904 has a connector double tee configuration and may be utilized in the substrate assembly 300 described above. The substrate block 1904 may be utilized as a connector substrate block in the substrate assembly 300 as will be discussed in greater detail below. Otherwise stated, the substrate block 1904 may be a substrate block 304 which is located between two end substrate blocks 304. The connector substrate blocks allow coupling of additional components 200 as well as routing of flow from the channels in each of the substrate blocks 304 to enable flexible configuration of the flow path. The substrate block 1904 has a fluid port 1910, the fluid port 1910 having a seal cavity 1912. The fluid port 1912 is formed into a seal side mounting surface 1914. Fastener passageways 1908 are also formed into the seal side mounting surface 1914 and extend through the substrate block 1904. A bottom surface 1916 is opposite the seal side mounting surface 1914.

The substrate block 1904 also has opposing mating surfaces 1928. The substrate block 1904 has a length L measured from the first mating surface 1928 to the second mating surface 1928. Coupling holes 1918 extend from one mating surface 1928 to the other mating surface 1928 to allow passage of the fasteners 320 as described above. The mating surfaces 1928 each have a female connector 1930 and a male connector 1940. The female connector 1930 has a cylindrical cavity 1931 formed into the mating surface 1928. The cylindrical cavity 1931 terminates in a floor 1932. An annular groove 1933 is formed into the floor 1932. Optionally, the annular groove 1933 may have an outer diameter equal to a diameter of the cylindrical cavity 1931 or may have an outer diameter which is less than a diameter of the cylindrical cavity 1931.

The male connectors 1940 each have a cylindrical protuberance 1941 extending from the mating surface 1928. The cylindrical protuberance 1941 terminates in a distal end 1942. An annular ring 1943 extends from the distal end 1942. Optionally, the annular ring 1943 may have an outer diameter which is equal to a diameter of the cylindrical protuberance 1941 or the outer diameter of the annular ring 1943 may be less than a diameter of the cylindrical protuberance 1941. The annular ring 1943 also has an inner diameter which is greater than a diameter of the channel 1924 such that the distal end 1942 of the cylindrical protuberance 1941 forms an end surface of the cylindrical protuberance 1941 and the annular ring 1943 protrudes from the end surface.

The male connectors 1940 are configured to couple to a female connector of another substrate block 304 and provide a fluid-tight connection between the male and female connectors. Similarly, the female connectors 1930 are configured to couple to a male connector of another substrate block 304 and provide a fluid-tight connection between the male and female connectors. The male connectors 1940 are configured to interface with any of the female connectors of the substrate blocks 304 and vice versa. This may be achieved by a close fit or interference fit between the respective surfaces. For example, a seal may be achieved by the outer diameter of the annular ring 1943 or the diameter of the cylindrical protuberance 1941 being greater than the diameter of the cylindrical cavity 1930 or the outer diameter of the annular groove 1933. Similarly, the inner diameter of the annular ring 1943 may be less than the inner diameter of the annular groove 1933. In other configurations, the end surface of the annular ring 1943 may be configured to form a seal with a bottom surface of the annular ring 1943. In yet other configurations, the distal end 1942 of the cylindrical protuberance 1941 may form a seal with the floor 1932 of the female connector 1930. The fasteners 320 may be used to compress the substrate blocks 304 and ensure that the male and female connectors remain mated. Other mating geometries are contemplated, with the goal of any connector geometry being to provide a fluid-tight connection between substrate blocks 304 within the substrate assembly 300.

As can be seen, the connector double tee configuration of the substrate block 1904 has a flow path extending from the fluid port 1910 to the male connector 1940 on the first mating surface 1928 and the female connector 1930 on the second mating surface 1928. A first channel 1924 extends from the floor 1932 of the cylindrical cavity 1931 of the female connector 1930 on the second mating surface 1928 to the distal end 1942 of the cylindrical protuberance 1941 of the male connector 1940 on the first mating surface 1928. In addition, the flow path extends from the fluid port 1910 to the female connector 1930 on the first mating surface 1928 and the male connector 1940 on the second mating surface 1928. A second channel 1924 extends from the floor 1932 of the cylindrical cavity 1931 of the female connector 1930 on the first mating surface 1928 to the distal end 1942 of the cylindrical protuberance 1941 of the male connector 1940 on the second mating surface 1928. A first passage 1926 extends from the first channel 1924 to the fluid port 1910. A second passage 1926 extends from the second channel 1924 to the fluid port 1910. Thus, the fluid port 1910 is in fluid communication with each of the male and female connectors 1940, 1930 on both the first and second mating surfaces 1928.

It is conceived that the substrate assembly 300, comprising any of the disclosed substrate blocks in any configuration, may be utilized. This will allow flexible mounting of the required components 200 to achieve any desired flow path routing and allow flexible arrangement of the components 200 as needed. It is further contemplated that components 200 may be incorporated into the substrate assembly 300 to achieve increased packaging density or other goals for the system. For example, the substrate blocks 304 may include a component 200 which serves as a flow mixer, check valve, or any other component. The component 200 may not be mounted onto the seal side mounting surface of the substrate assembly 300, but instead may form a part of the substrate assembly and have additional components 200 mounted thereon. As is apparent, the substrate assembly 300 may be utilized in a modular manner to enable flexible design and assembly without the need for a large number of unique substrate blocks 104 each having a specific purpose.

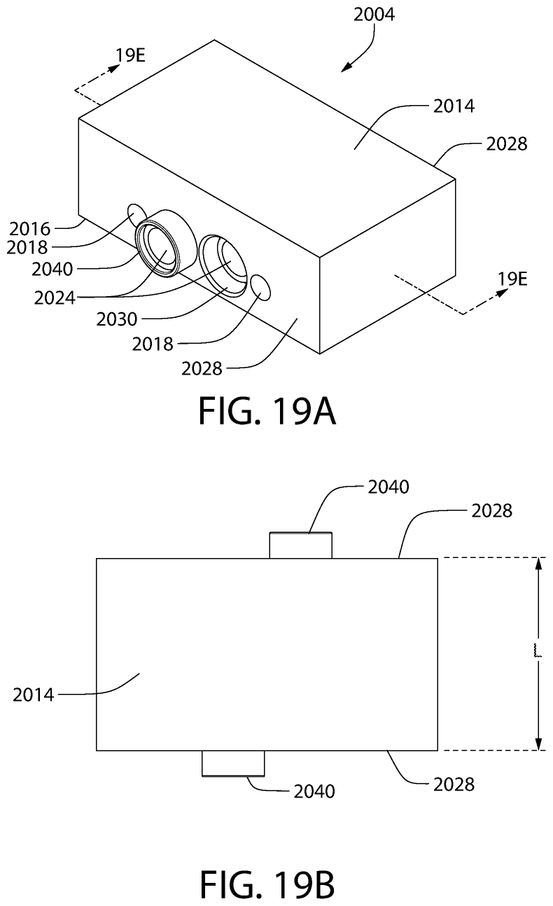

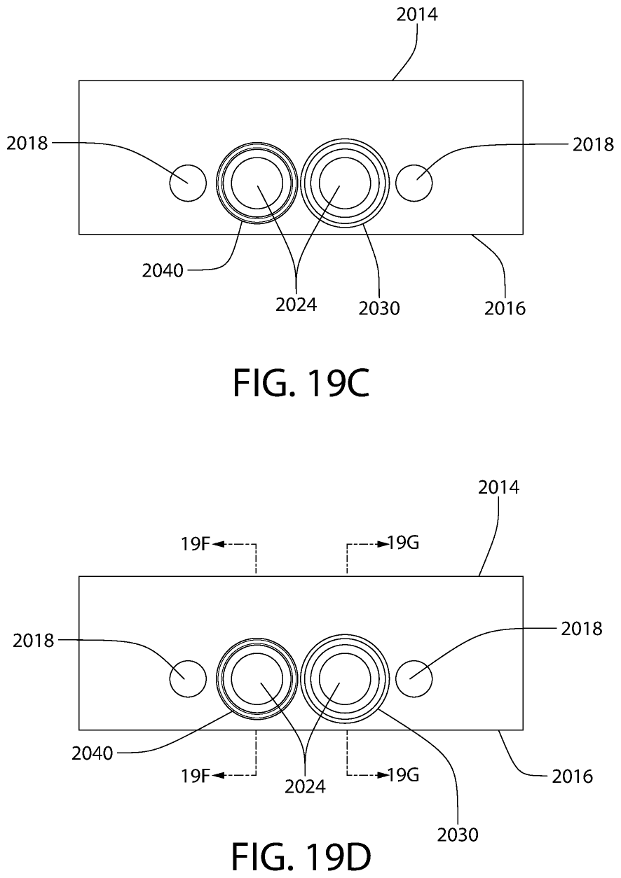

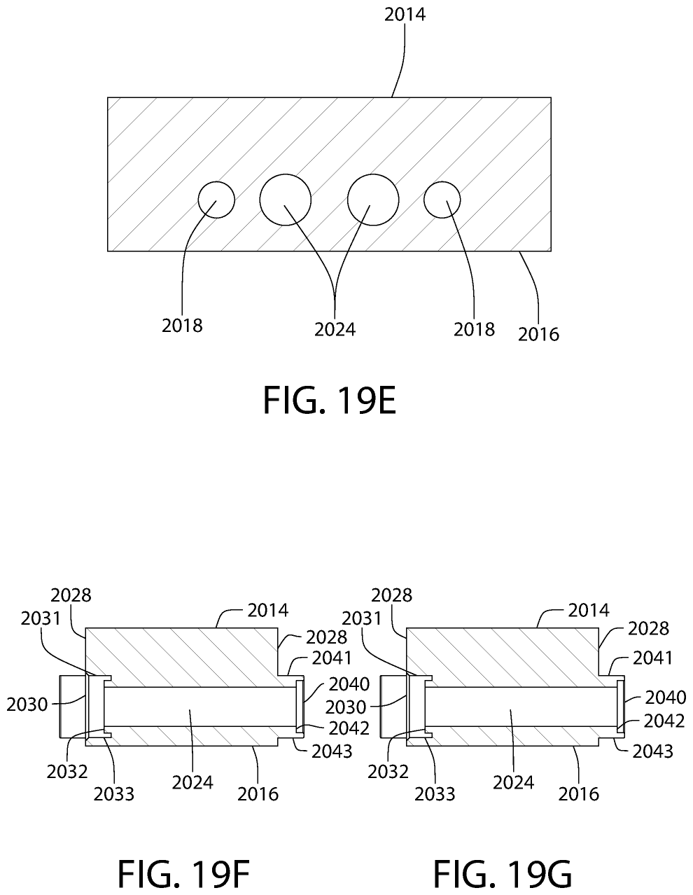

Turning to FIGS. 19A-G, a substrate block 2004 is illustrated. The substrate block 2004 has a spacer configuration and may be utilized in the substrate assembly 300 described above. The substrate block 2004 may be utilized as a connector substrate block in the substrate assembly 300 as will be discussed in greater detail below. Otherwise stated, the substrate block 2004 may be a substrate block 304 which is located between two end substrate blocks 304. The connector substrate blocks allow coupling of additional components 200 as well as routing of flow from the channels in each of the substrate blocks 304 to enable flexible configuration of the flow path. The substrate block 2004 does not have a fluid port or fastener passageways. The substrate block 2004 forms a part of the fluid flow path and is sized to allow mounting of components 200 on other substrate blocks 304 within the substrate assembly 300. The substrate block has a seal side mounting surface 2014 which is coplanar with the seal side mounting surfaces of the other substrate blocks 304. A bottom surface 2016 is opposite the seal side mounting surface 2014.

The substrate block 2004 also has opposing mating surfaces 2028. The substrate block 2004 has a length L measured from the first mating surface 2028 to the second mating surface 2028. The length L of the substrate block 2004 may be greater than or less than the length L of the other substrate blocks. Optionally, the length L of the substrate block 2004 may be equal to the length L of the other substrate blocks but need not have any specific length to allow the fitment of a variety of components 200 having different port spacing or other dimensional constraints. Generally, the aforementioned substrate blocks all have the same length L. The substrate block 2004 may have a greater length than the length of the other substrate blocks.

Coupling holes 2018 extend from one mating surface 2028 to the other mating surface 2028 to allow passage of the fasteners 320 as described above. The mating surfaces 2028 each have a female connector 2030 and a male connector 2040. The female connector 2030 has a cylindrical cavity 2031 formed into the mating surface 2028. The cylindrical cavity 2031 terminates in a floor 2032. An annular groove 2033 is formed into the floor 2032. Optionally, the annular groove 2033 may have an outer diameter equal to a diameter of the cylindrical cavity 2031 or may have an outer diameter which is less than a diameter of the cylindrical cavity 2031.

The male connectors 2040 each have a cylindrical protuberance 2041 extending from the mating surface 2028. The cylindrical protuberance 2041 terminates in a distal end 2042. An annular ring 2043 extends from the distal end 2042. Optionally, the annular ring 2043 may have an outer diameter which is equal to a diameter of the cylindrical protuberance 2041 or the outer diameter of the annular ring 2043 may be less than a diameter of the cylindrical protuberance 2041. The annular ring 2043 also has an inner diameter which is greater than a diameter of the channel 2024 such that the distal end 2042 of the cylindrical protuberance 2041 forms an end surface of the cylindrical protuberance 2041 and the annular ring 2043 protrudes from the end surface.

The male connectors 2040 are configured to couple to a female connector of another substrate block 304 and provide a fluid-tight connection between the male and female connectors. Similarly, the female connectors 2030 are configured to couple to a male connector of another substrate block 304 and provide a fluid-tight connection between the male and female connectors. The male connectors 2040 are configured to interface with any of the female connectors of the substrate blocks 304 and vice versa. This may be achieved by a close fit or interference fit between the respective surfaces. For example, a seal may be achieved by the outer diameter of the annular ring 2043 or the diameter of the cylindrical protuberance 2041 being greater than the diameter of the cylindrical cavity 2030 or the outer diameter of the annular groove 2033. Similarly, the inner diameter of the annular ring 2043 may be less than the inner diameter of the annular groove 2033. In other configurations, the end surface of the annular ring 2043 may be configured to form a seal with a bottom surface of the annular ring 2043. In yet other configurations, the distal end 2042 of the cylindrical protuberance 2041 may form a seal with the floor 2032 of the female connector 2030. The fasteners 320 may be used to compress the substrate blocks 304 and ensure that the male and female connectors remain mated. Other mating geometries are contemplated, with the goal of any connector geometry being to provide a fluid-tight connection between substrate blocks 304 within the substrate assembly 300.

As can be seen, the spacer configuration of the substrate block 2004 has a flow path extending from the male connector 2040 on the first mating surface 2028 and the female connector 2030 on the second mating surface 2028. A first channel 2024 extends from the floor 2032 of the cylindrical cavity 2031 of the female connector 2030 on the second mating surface 2028 to the distal end 2042 of the cylindrical protuberance 2041 of the male connector 2040 on the first mating surface 2028. A second channel 2024 extends from the floor 2032 of the cylindrical cavity 2031 of the female connector 2030 on the first mating surface 2028 to the distal end 2042 of the cylindrical protuberance 2041 of the male connector 2040 on the second mating surface 2028. Thus, two parallel channels 2024 form first and second flow paths through the substrate block 2004.

It is conceived that the substrate assembly 300, comprising any of the disclosed substrate blocks in any configuration, may be utilized. This will allow flexible mounting of the required components 200 to achieve any desired flow path routing and allow flexible arrangement of the components 200 as needed. It is further contemplated that components 200 may be incorporated into the substrate assembly 300 to achieve increased packaging density or other goals for the system. For example, the substrate blocks 304 may include a component 200 which serves as a flow mixer, check valve, or any other component. The component 200 may not be mounted onto the seal side mounting surface of the substrate assembly 300, but instead may form a part of the substrate assembly and have additional components 200 mounted thereon. As is apparent, the substrate assembly 300 may be utilized in a modular manner to enable flexible design and assembly without the need for a large number of unique substrate blocks 104 each having a specific purpose.

### Exemplary Claim Set

Exemplary claim 1: A system for processing articles, the system comprising: a fluid supply configured to supply a process fluid; a process chamber configured to process articles; and a fluid delivery module, the fluid delivery module comprising: an inlet fluidly coupled to the fluid supply; an outlet fluidly coupled to the process chamber; a flow passage extending from the inlet to the outlet; a substrate panel; a first component for controlling flow, the first component comprising a first port comprising a seal cavity, a second port comprising a seal cavity, and a first flow path extending from the first port to the second port, the first flow path forming a first portion of the flow passage; a substrate assembly mounted to the substrate panel, the substrate assembly comprising: a first substrate block comprising a first port, a first male connector, and a first female connector, the first port comprising a seal cavity; a second substrate block comprising a first port, a first male connector, and a first female connector, the first port comprising a seal cavity, a second flow path extending from the first port of the first substrate block to the first port of the second substrate block, the second flow path forming a second portion of the flow passage; a seal positioned within the seal cavity of the first port of the first component and the seal cavity of the first port of the first substrate block; wherein the first port of the first component is coupled to the first port of the first substrate block of the substrate assembly so that the first flow path is fluidly coupled to the second flow path.

Exemplary claim 2: The system of exemplary claim 1 wherein the first male connector of the first substrate block is coupled to the first female connector of the second substrate block.

Exemplary claim 3: The system of exemplary claim 2 wherein the first female connector of the first substrate block is coupled to the first male connector of the second substrate block.

Exemplary claim 4: The system of exemplary claim 2 or exemplary claim 3 wherein the first male connector of the first substrate block forms a fluid-tight connection with the first female connector of the second substrate block.

Exemplary claim 5: The system of any one of exemplary claims 1 to 4 wherein the second substrate block further comprises a second male connector and a second female connector.

Exemplary claim 6: The system of exemplary claim 5 wherein the second substrate block further comprises a channel, the channel extending from the first male connector of the second substrate block to the second female connector of the second substrate block.

Exemplary claim 7: The system of exemplary claim 6 wherein the second substrate block comprises a passage, the passage extending from the first port of the second substrate block to the channel.

Exemplary claim 8: The system of exemplary claim 6 or exemplary claim 7 wherein the second substrate block further comprises a second channel extending from the second male connector of the second substrate block to the first female connector of the second substrate block, the second channel extending parallel to the channel.

Exemplary claim 9: The system of exemplary claim 8 wherein the second substrate block comprises a second passage, the second passage extending from the first port of the second substrate block to the second channel.

Exemplary claim 10: The system of any one of exemplary claims 1 to 9 wherein the substrate assembly further comprises a third substrate block, the third substrate block comprising a first male connector, a first female connector, a second male connector, and a second female connector, the third substrate block coupled to the second substrate block.

Exemplary claim 11: The system of exemplary claim 10 wherein the second flow path extends through the third substrate block.

Exemplary claim 12: The system of exemplary claim 10 or exemplary claim 11 wherein the third substrate block comprises a first port.

Exemplary claim 13: The system of exemplary claim 10 or exemplary claim 11 wherein the third substrate block is free of ports.

Exemplary claim 14: The system of any one of exemplary claims 1 to 13 wherein the substrate assembly further comprises a longitudinal axis extending through the first substrate block and the second substrate block, the first and second substrate blocks each having a length measured along the longitudinal axis, wherein the length of the first substrate block and the second substrate block are equal.

Exemplary claim 15: The system of exemplary claim 14 further comprising a third substrate block, the third substrate block having a length measured along the longitudinal axis, the length of the third substrate block being different than the lengths of the first and second substrate blocks.

Exemplary claim 16: The system of exemplary claim 15 wherein the length of the third substrate block is greater than the lengths of the first and second substrate blocks.

Exemplary claim 17: The system of any one of exemplary claims 1 to 16 wherein the first substrate block forms a tee.

Exemplary claim 18: The system of any one of exemplary claims 1 to 16 wherein the first substrate block further comprises a tube portion, the tube portion fluidly coupled to the first port.

Exemplary claim 19: The system of any one of exemplary claims 1 to 18 wherein the substrate assembly further comprises a first fastener, and a second fastener, the first and second fasteners extending through the first and second substrate blocks.

Exemplary claim 20: The system of exemplary claim 19 wherein the substrate assembly further comprises a longitudinal axis, the first and second fasteners extending parallel to the longitudinal axis.

Exemplary claim 21: The system of any one of exemplary claims 1 to 20 wherein the first male connector of the first substrate block comprises a cylindrical protuberance and an annular ring extending from a distal end of the cylindrical protuberance.

Exemplary claim 22: The system of any one of exemplary claims 1 to 21 wherein the first female connector of the first substrate block comprises a cylindrical cavity and an annular groove, the annular groove formed into a floor of the cylindrical cavity.

Exemplary claim 23: A system for processing articles, the system comprising: a fluid supply configured to supply a process fluid; a process chamber configured to process articles; and a fluid delivery module, the fluid delivery module comprising: an inlet fluidly coupled to the fluid supply; an outlet fluidly coupled to the process chamber; a flow passage extending from the inlet to the outlet; a substrate panel; a first component for controlling flow, the first component comprising a first port, a second port, and a first flow path extending from the first port to the second port, the first flow path forming a first portion of the flow passage; a substrate assembly mounted to the substrate panel, the substrate assembly comprising: a first substrate block comprising a first port, a first male connector, and a first female connector; a second substrate block comprising a first port, a first male connector, a first female connector, the first male connector of the first substrate block coupled to the first female connector of the second substrate block and the first female connector of the first substrate block coupled to the first male connector of the second substrate block, a second flow path extending from the first port of the first substrate block to the first port of the second substrate block, the second flow path forming a second portion of the flow passage; wherein the first port of the first component is coupled to the first port of the first substrate block of the substrate assembly so that the first flow path is fluidly coupled to the second flow path.

Exemplary claim 24: The system of exemplary claim 23 wherein the first male connector of the first substrate block forms a fluid-tight connection with the first female connector of the second substrate block.

Exemplary claim 25: The system of exemplary claim 23 or exemplary claim 24 wherein the second substrate block further comprises a second male connector and a second female connector.

Exemplary claim 26: The system of exemplary claim 25 wherein the second substrate block further comprises a channel, the channel extending from the first male connector of the second substrate block to the second female connector of the second substrate block.

Exemplary claim 27: The system of exemplary claim 26 wherein the second substrate block comprises a passage, the passage extending from the first port of the second substrate block to the channel.

Exemplary claim 28: The system of exemplary claim 26 or exemplary claim 27 wherein the second substrate block further comprises a second channel extending from the second male connector of the second substrate block to the first female connector of the second substrate block, the second channel extending parallel to the channel.

Exemplary claim 29: The system of exemplary claim 28 wherein the second substrate block comprises a second passage, the second passage extending from the first port of the second substrate block to the second channel.

Exemplary claim 30: The system of any one of exemplary claims 23 to 29 wherein the substrate assembly further comprises a third substrate block, the third substrate block comprising a first male connector, a first female connector, a second male connector, and a second female connector, the third substrate block coupled to the second substrate block.

Exemplary claim 31: The system of exemplary claim 30 wherein the second flow path extends through the third substrate block.

Exemplary claim 32: The system of exemplary claim 30 or exemplary claim 31 wherein the third substrate block comprises a first port.

Exemplary claim 33: The system of exemplary claim 30 or exemplary claim 31 wherein the third substrate block is free of ports.

Exemplary claim 34: The system of any one of exemplary claims 23 to 33 wherein the substrate assembly further comprises a longitudinal axis extending through the first substrate block and the second substrate block, the first and second substrate blocks each having a length measured along the longitudinal axis, wherein the length of the first substrate block and the second substrate block are equal.

Exemplary claim 35: The system of exemplary claim 34 further comprising a third substrate block, the third substrate block having a length measured along the longitudinal axis, the length of the third substrate block being different than the lengths of the first and second substrate blocks.

Exemplary claim 36: The system of exemplary claim 35 wherein the length of the third substrate block is greater than the lengths of the first and second substrate blocks.

Exemplary claim 37: The system of any one of exemplary claims 23 to 36 wherein the first substrate block forms a tec.

Exemplary claim 38: The system of any one of exemplary claims 23 to 36 wherein the first substrate block further comprises a tube portion, the tube portion fluidly coupled to the first port.

Exemplary claim 39: The system of any one of exemplary claims 23 to 38 wherein the substrate assembly further comprises a first fastener, and a second fastener, the first and second fasteners extending through the first and second substrate blocks.

Exemplary claim 40: The system of exemplary claim 39 wherein the substrate assembly further comprises a longitudinal axis, the first and second fasteners extending parallel to the longitudinal axis.

Exemplary claim 41: The system of any one of exemplary claims 23 to 40 wherein the first male connector of the first substrate block comprises a cylindrical protuberance and an annular ring extending from a distal end of the cylindrical protuberance.

Exemplary claim 42: The system of any one of exemplary claims 23 to 41 wherein the first female connector of the first substrate block comprises a cylindrical cavity and an annular groove, the annular groove formed into a floor of the cylindrical cavity.

Exemplary claim 43: A substrate assembly comprising: a first substrate block comprising a first port, a first male connector, a first female connector, a first passage, and a first channel, the first passage extending from the first port to the first channel and the first channel extending from the first passage to the first male connector; a second substrate block comprising a first male connector, a first female connector, a second male connector, a second female connector, and a first channel extending from the first female connector to the second male connector; a first flow path extending from the first port to the second male connector via the first passage of the first substrate block, the first channel of the substrate block, and the first channel of the second substrate block.

Exemplary claim 44: The substrate assembly of exemplary claim 43 wherein the first male connector of the first substrate block is coupled to the first female connector of the second substrate block.

Exemplary claim 45: The substrate assembly of exemplary claim 44 wherein the first female connector of the first substrate block is coupled to the first male connector of the second substrate block.

Exemplary claim 46: The substrate assembly of exemplary claim 44 or exemplary claim 45 wherein the first male connector of the first substrate block forms a fluid-tight connection with the first female connector of the second substrate block.

Exemplary claim 47: The substrate assembly of any one of exemplary claims 43 to 46 wherein the second substrate block further comprises a second male connector and a second female connector.

Exemplary claim 48: The substrate assembly of exemplary claim 47 wherein the second substrate block further comprises a channel, the channel extending from the first male connector of the second substrate block to the second female connector of the second substrate block.

Exemplary claim 49: The substrate assembly of exemplary claim 48 wherein the second substrate block comprises a passage, the passage extending from the first port of the second substrate block to the channel.

Exemplary claim 50: The substrate assembly of exemplary claim 48 or exemplary claim 49 wherein the second substrate block further comprises a second channel extending from the second male connector of the second substrate block to the first female connector of the second substrate block, the second channel extending parallel to the channel.

Exemplary claim 51: The substrate assembly of exemplary claim 50 wherein the second substrate block comprises a second passage, the second passage extending from the first port of the second substrate block to the second channel.

Exemplary claim 52: The substrate assembly of any one of exemplary claims 43 to 51 wherein the substrate assembly further comprises a third substrate block, the third substrate block comprising a first male connector, a first female connector, a second male connector, and a second female connector, the third substrate block coupled to the second substrate block.

Exemplary claim 53: The substrate assembly of exemplary claim 52 wherein the first flow path extends through the third substrate block.

Exemplary claim 54: The substrate assembly of exemplary claim 52 or exemplary claim 53 wherein the third substrate block comprises a first port.

Exemplary claim 55: The substrate assembly of exemplary claim 52 or exemplary claim 53 wherein the third substrate block is free of ports.

Exemplary claim 56: The substrate assembly of any one of exemplary claims 43 to 55 further comprising a longitudinal axis extending through the first substrate block and the second substrate block, the first and second substrate blocks each having a length measured along the longitudinal axis, wherein the length of the first substrate block and the second substrate block are equal.

Exemplary claim 57: The substrate assembly of exemplary claim 56 further comprising a third substrate block, the third substrate block having a length measured along the longitudinal axis, the length of the third substrate block being different than the lengths of the first and second substrate blocks.

Exemplary claim 58: The substrate assembly of exemplary claim 57 wherein the length of the third substrate block is greater than the lengths of the first and second substrate blocks.

Exemplary claim 59: The substrate assembly of any one of exemplary claims 43 to 58 wherein the first substrate block forms a tec.

Exemplary claim 60: The substrate assembly of any one of exemplary claims 43 to 59 wherein the first substrate block further comprises a tube portion, the tube portion fluidly coupled to the first port.

Exemplary claim 61: The substrate assembly of any one of exemplary claims 43 to 60 wherein the substrate assembly further comprises a first fastener, and a second fastener, the first and second fasteners extending through the first and second substrate blocks.

Exemplary claim 62: The substrate assembly of exemplary claim 61 wherein the substrate assembly further comprises a longitudinal axis, the first and second fasteners extending parallel to the longitudinal axis.

Exemplary claim 63: The substrate assembly of any one of exemplary claims 43 to 62 wherein the first male connector of the first substrate block comprises a cylindrical protuberance and an annular ring extending from a distal end of the cylindrical protuberance.

Exemplary claim 64: The substrate assembly of any one of exemplary claims 43 to 63 wherein the first female connector of the first substrate block comprises a cylindrical cavity and an annular groove, the annular groove formed into a floor of the cylindrical cavity.

Exemplary claim 65: A substrate assembly comprising: first and second end substrate blocks, each of the first and second end substrate blocks comprising a first port and a first connector; and a plurality of connector substrate blocks, each of the plurality of connector substrate blocks comprising a first connector and a second connector; wherein the first end substrate block is joined to a first one of the plurality of connector substrate blocks, the first connector of the first end substrate block engaging the first connector of the first one of the plurality of connector substrate blocks; wherein the second end substrate block is joined to a second one of the plurality of connector substrate blocks, the first connector of the second end substrate block engaging the second connector of the second one of the plurality of connector substrate blocks; and wherein a first flow path extends from the first port of the first end substrate block through the first connector of the first end substrate block to the first one of the plurality of connector substrate blocks.

Exemplary claim 66: The substrate assembly of exemplary claim 65 wherein the first connector of the first end substrate block is coupled to the first connector of the first one of the plurality of connector substrate blocks.

Exemplary claim 67: The substrate assembly of exemplary claim 66 wherein the first connector of the first end substrate block forms a fluid-tight connection with the first one of the plurality of connector substrate blocks.

Exemplary claim 68: The substrate assembly of any one of exemplary claims 65 to 67 wherein the plurality of connector substrate blocks each further comprise a third connector and a fourth connector.

Exemplary claim 69: The substrate assembly of exemplary claim 68 wherein the first one of the plurality of connector substrate blocks further comprises a channel, the channel extending from the first connector of the first one of the plurality of connector substrate blocks to the third connector of the first one of the plurality of connector substrate blocks.

Exemplary claim 70: The substrate assembly of exemplary claim 69 wherein the first one of the plurality of connector substrate blocks comprises a first port and a passage, the passage extending from the first port of the first one of the plurality of connector substrate blocks to the channel.

Exemplary claim 71: The substrate assembly of exemplary claim 69 or exemplary claim 70 wherein the first one of the plurality of connector substrate blocks further comprises a second channel extending from the second connector of the first one of the plurality of connector substrate blocks to the fourth connector of the first one of the plurality of connector substrate blocks, the second channel extending parallel to the channel.

Exemplary claim 72: The substrate assembly of exemplary claim 65 wherein the first flow path extends through the second end substrate block.

Exemplary claim 73: The substrate assembly of any one of exemplary claims 65 to 72 further comprising a longitudinal axis extending through the first and second end substrate blocks, the first and second end substrate blocks each having a length measured along the longitudinal axis, wherein the length of the first end substrate block and the second end substrate block are equal.

Exemplary claim 74: The substrate assembly of exemplary claim 73 wherein the first one of the plurality of connector substrate blocks has a length measured along the longitudinal axis, the length of the first one of the plurality of connector substrate blocks being different than the lengths of the first and second end substrate blocks.

Exemplary claim 75: The substrate assembly of exemplary claim 74 wherein the length of the first one of the plurality of connector substrate blocks is greater than the lengths of the first and second end substrate blocks.

Exemplary claim 76: The substrate assembly of any one of exemplary claims 65 to 75 wherein the first end substrate block forms a tec.

Exemplary claim 77: The substrate assembly of any one of exemplary claims 65 to 76 wherein the first end substrate block further comprises a tube portion, the tube portion fluidly coupled to the first port.

Exemplary claim 78: The substrate assembly of any one of exemplary claims 65 to 77 further comprising a first fastener, and a second fastener, the first and second fasteners extending through the first and second end substrate blocks.

Exemplary claim 79: The substrate assembly of exemplary claim 78 further comprising a longitudinal axis, the first and second fasteners extending parallel to the longitudinal axis.

Exemplary claim 80: The substrate assembly of any one of exemplary claims 65 to 79 wherein the first connector of the first end substrate block comprises a cylindrical protuberance and an annular ring extending from a distal end of the cylindrical protuberance.

Exemplary claim 81: The substrate assembly of any one of exemplary claims 65 to 79 wherein the first connector of the first end substrate block comprises a cylindrical cavity and an annular groove, the annular groove formed into a floor of the cylindrical cavity.

Exemplary claim 82: A system for processing articles, the system comprising: a fluid supply configured to supply a process fluid; a process chamber configured to process articles; and a fluid delivery module, the fluid delivery module comprising: an inlet fluidly coupled to the fluid supply; an outlet fluidly coupled to the process chamber; a flow passage extending from the inlet to the outlet; a substrate panel; a first component for controlling flow, the first component comprising a first port, a second port, and a first flow path extending from the first port to the second port, the first flow path forming a first portion of the flow passage; a substrate assembly mounted to the substrate panel, the substrate assembly comprising: first and second end substrate blocks, each of the first and second end substrate blocks comprising a first port and a first connector; and a plurality of connector substrate blocks, each of the plurality of connector substrate blocks comprising a first connector and a second connector; wherein the first end substrate block is joined to a first one of the plurality of connector substrate blocks, the first connector of the first end substrate block engaging the first connector of the first one of the plurality of connector substrate blocks; wherein the second end substrate block is joined to a second one of the plurality of connector substrate blocks, the first connector of the second end substrate block engaging the second connector of the second one of the plurality of connector substrate blocks; wherein a second flow path extends from the first port of the first end substrate block through the first connector of the first end substrate block to the first one of the plurality of connector substrate blocks, the second flow path forming a second portion of the flow passage; and wherein the first port of the first component is coupled to the first port of the first end substrate block of the substrate assembly so that the first flow path is fluidly coupled to the second flow path.

Exemplary claim 83: The system of exemplary claim 82 wherein the first connector of the first end substrate block is coupled to the first connector of the first one of the plurality of connector substrate blocks.

Exemplary claim 84: The system of exemplary claim 83 wherein the first connector of the first end substrate block forms a fluid-tight connection with the first one of the plurality of connector substrate blocks.

Exemplary claim 85: The system of any one of exemplary claims 82 to 84 wherein the plurality of connector substrate blocks each further comprise a third connector and a fourth connector.

Exemplary claim 86: The system of exemplary claim 85 wherein the first one of the plurality of connector substrate blocks further comprises a channel, the channel extending from the first connector of the first one of the plurality of connector substrate blocks to the third connector of the first one of the plurality of connector substrate blocks.

Exemplary claim 87: The system of exemplary claim 86 wherein the first one of the plurality of connector substrate blocks comprises a first port and a passage, the passage extending from the first port of the first one of the plurality of connector substrate blocks to the channel.

Exemplary claim 88: The system of exemplary claim 86 or exemplary claim 87 wherein the first one of the plurality of connector substrate blocks further comprises a second channel extending from the second connector of the first one of the plurality of connector substrate blocks to the fourth connector of the first one of the plurality of connector substrate blocks, the second channel extending parallel to the channel.

Exemplary claim 89: The system of any one of exemplary claims 82 to 88 wherein the first second path extends through the second end substrate block.

Exemplary claim 90: The system of any one of exemplary claims 82 to 89 wherein the substrate assembly further comprises a longitudinal axis extending through the first and second end substrate blocks, the first and second end substrate blocks each having a length measured along the longitudinal axis, wherein the length of the first end substrate block and the second end substrate block are equal.

Exemplary claim 91: The system of exemplary claim 90 wherein the first one of the plurality of connector substrate blocks has a length measured along the longitudinal axis, the length of the first one of the plurality of connector substrate blocks being different than the lengths of the first and second end substrate blocks.

Exemplary claim 92: The system of exemplary claim 91 wherein the length of the first one of the plurality of connector substrate blocks is greater than the lengths of the first and second end substrate blocks.

Exemplary claim 93: The system of any one of exemplary claims 82 to 92 wherein the first end substrate block forms a tec.

Exemplary claim 94: The system of any one of exemplary claims 82 to 93 wherein the first end substrate block further comprises a tube portion, the tube portion fluidly coupled to the first port.

Exemplary claim 95: The system of any one of exemplary claims 82 to 94 further comprising a first fastener, and a second fastener, the first and second fasteners extending through the first and second end substrate blocks.

Exemplary claim 96: The system of exemplary claim 95 further comprising a longitudinal axis, the first and second fasteners extending parallel to the longitudinal axis.

Exemplary claim 97: The system of any one of exemplary claims 82 to 96 wherein the first connector of the first end substrate block comprises a cylindrical protuberance and an annular ring extending from a distal end of the cylindrical protuberance.

Exemplary claim 98: The system of any one of exemplary claims 82 to 96 wherein the first connector of the first end substrate block comprises a cylindrical cavity and an annular groove, the annular groove formed into a floor of the cylindrical cavity.

While the invention has been described with respect to specific examples including presently preferred modes of carrying out the invention, those skilled in the art will appreciate that there are numerous variations and permutations of the above-described systems and techniques. It is to be understood that other embodiments may be utilized, and structural and functional modifications may be made without departing from the scope of the present invention. Thus, the spirit and scope of the invention should be construed broadly as set forth in the appended claims.

1. A system for processing articles, the system comprising:
a fluid supply configured to supply a process fluid;
a process chamber configured to process articles; and
a fluid delivery module, the fluid delivery module comprising:
an inlet fluidly coupled to the fluid supply;
an outlet fluidly coupled to the process chamber;
a flow passage extending from the inlet to the outlet;
a substrate panel;
a first component for controlling flow, the first component comprising a first port comprising a seal cavity, a second port comprising a seal cavity, and a first flow path extending from the first port to the second port, the first flow path forming a first portion of the flow passage;
a substrate assembly mounted to the substrate panel, the substrate assembly comprising:
a first substrate block comprising a first port, a first male connector, and a first female connector, the first port comprising a seal cavity;
a second substrate block comprising a first port, a first male connector, and a first female connector, the first port comprising a seal cavity, a second flow path extending from the first port of the first substrate block to the first port of the second substrate block, the second flow path forming a second portion of the flow passage;
a seal positioned within the seal cavity of the first port of the first component and the seal cavity of the first port of the first substrate block;
wherein the first port of the first component is coupled to the first port of the first substrate block of the substrate assembly so that the first flow path is fluidly coupled to the second flow path.

2. The system of claim 1 wherein the first male connector of the first substrate block is coupled to the first female connector of the second substrate block.

3. (canceled)

4. The system of claim 2 wherein the first male connector of the first substrate block forms a fluid-tight connection with the first female connector of the second substrate block.

5. The system of claim 1 wherein the second substrate block further comprises a second male connector and a second female connector.

6. The system of claim 5 wherein the second substrate block further comprises a channel, the channel extending from the first male connector of the second substrate block to the second female connector of the second substrate block.

7. The system of claim 6 wherein the second substrate block comprises a passage, the passage extending from the first port of the second substrate block to the channel.

8. The system of claim 6 wherein the second substrate block further comprises a second channel extending from the second male connector of the second substrate block to the first female connector of the second substrate block, the second channel extending parallel to the channel and wherein the second substrate block comprises a second passage, the second passage extending from the first port of the second substrate block to the second channel.

9. (canceled)

10. The system of claim 1 wherein the substrate assembly further comprises a third substrate block, the third substrate block comprising a first male connector, a first female connector, a second male connector, and a second female connector, the third substrate block coupled to the second substrate block.

11.-13. (canceled)

14. The system of claim 1 wherein the substrate assembly further comprises a longitudinal axis extending through the first substrate block and the second substrate block, the first and second substrate blocks each having a length measured along the longitudinal axis, wherein the length of the first substrate block and the second substrate block are equal.

15. The system of claim 14 further comprising a third substrate block, the third substrate block having a length measured along the longitudinal axis, the length of the third substrate block being different than the lengths of the first and second substrate blocks.

16. (canceled)

17. (canceled)

18. The system of claim 1 wherein the first substrate block further comprises a tube portion, the tube portion fluidly coupled to the first port.

19. The system of claim 1 wherein the substrate assembly further comprises a first fastener, and a second fastener, and a longitudinal axis, the first and second fasteners extending through the first and second substrate blocks in a direction parallel to the longitudinal axis.

20. (canceled)

21. The system of claim 1 wherein the first male connector of the first substrate block comprises a cylindrical protuberance and an annular ring extending from a distal end of the cylindrical protuberance.

22. The system of claim 1 wherein the first female connector of the first substrate block comprises a cylindrical cavity and an annular groove, the annular groove formed into a floor of the cylindrical cavity.

23.-42. (canceled)

43. A substrate assembly comprising:
a first substrate block comprising a first port, a first male connector, a first female connector, a first passage, and a first channel, the first passage extending from the first port to the first channel and the first channel extending from the first passage to the first male connector;
a second substrate block comprising a first male connector, a first female connector, a second male connector, a second female connector, and a first channel extending from the first female connector to the second male connector;
a first flow path extending from the first port to the second male connector via the first passage of the first substrate block, the first channel of the substrate block, and the first channel of the second substrate block.

44.-46. (canceled)

47. The substrate assembly of claim 43 wherein the second substrate block further comprises a second male connector and a second female connector, wherein the second substrate block further comprises a channel, the channel extending from the first male connector of the second substrate block to the second female connector of the second substrate block, and wherein the second substrate block comprises a passage, the passage extending from the first port of the second substrate block to the channel.

48. (canceled)

49. The substrate assembly of claim 47 wherein the second substrate block comprises a passage, the passage extending from the first port of the second substrate block to the channel.

50.-81. (canceled)

82. A system for processing articles, the system comprising:
a fluid supply configured to supply a process fluid;
a process chamber configured to process articles; and
a fluid delivery module, the fluid delivery module comprising:
an inlet fluidly coupled to the fluid supply;
an outlet fluidly coupled to the process chamber;
a flow passage extending from the inlet to the outlet;
a substrate panel;
a first component for controlling flow, the first component comprising a first port, a second port, and a first flow path extending from the first port to the second port, the first flow path forming a first portion of the flow passage;
a substrate assembly mounted to the substrate panel, the substrate assembly comprising:
first and second end substrate blocks, each of the first and second end substrate blocks comprising a first port and a first connector; and
a plurality of connector substrate blocks, each of the plurality of connector substrate blocks comprising a first connector and a second connector;
wherein the first end substrate block is joined to a first one of the plurality of connector substrate blocks, the first connector of the first end substrate block engaging the first connector of the first one of the plurality of connector substrate blocks;
wherein the second end substrate block is joined to a second one of the plurality of connector substrate blocks, the first connector of the second end substrate block engaging the second connector of the second one of the plurality of connector substrate blocks;
wherein a second flow path extends from the first port of the first end substrate block through the first connector of the first end substrate block to the first one of the plurality of connector substrate blocks, the second flow path forming a second portion of the flow passage; and
wherein the first port of the first component is coupled to the first port of the first end substrate block of the substrate assembly so that the first flow path is fluidly coupled to the second flow path.

83. (canceled)

84. (canceled)

85. The system of claim 82 wherein the plurality of connector substrate blocks each further comprise a third connector and a fourth connector.

86. The system of claim 85 wherein the first one of the plurality of connector substrate blocks further comprises a channel, the channel extending from the first connector of the first one of the plurality of connector substrate blocks to the third connector of the first one of the plurality of connector substrate blocks.

87.-98. (canceled)
